(19) United States
(12) Patent Application Publication
(10) Pub. No.: US 2024/0288968 A1
(43) Pub. Date: Aug. 29, 2024

(54) DISPLAY DEVICE

(71) Applicant: Samsung Display Co., Ltd., Yongin-Si (KR)

(72) Inventor: DONGCHUN LEE, Yongin-si (KR)

(21) Appl. No.: 18/536,234

(22) Filed: Dec. 12, 2023

(30) Foreign Application Priority Data
Feb. 28, 2023 (KR) 10-2023-0027135

(51) Int. Cl. G06F 3/041; G06F 3/044

(52) U.S. Cl. CPC G06F 3/04166; G06F 3/0412; G06F 3/04164; G06F 3/0418; G06F 3/0443

(57) ABSTRACT

Disclosed is a display device. The display device includes a display panel that displays an image, an input sensor disposed on the display panel and including a sensing area and a sensing peripheral area excluding the sensing area, and a sensor controller that drives the sensing area. The input sensor includes a plurality of sensing electrodes arranged in a first direction and a second direction perpendicular to the first direction, and an auxiliary unit disposed on one side of at least one of the sensing electrodes. A main sensing electrode among the sensing electrodes receives a main sensing signal from the sensor controller, a peripheral sensing electrode adjacent to the main sensing electrode among the sensing electrodes receives a peripheral sensing signal from the sensor controller, and the auxiliary unit receives an auxiliary transmission signal having an inverted phase from the peripheral sensing signal from the sensor controller.

### CROSS-REFERENCE TO RELATED APPLICATIONS

This application claims priority, under 35 U.S.C. § 119, to Korean Patent Application No. 10-2023-0027135 filed on Feb. 28, 2023 in the Korean Intellectual Property Office, the disclosure of which is incorporated by reference herein.

### BACKGROUND

Embodiments of the present disclosure described herein relate to a display device, and more particularly, to a display device including an input sensor.

In general, an electronic device such as a smart phone, a digital camera, a laptop computer, a navigation device, a smart television, and the like that provides an image to a user includes a display device for displaying an image. The display device generates an image and provides the generated image to a user through a display screen.

A display device includes a display panel for generating an image and an input sensing unit disposed on the display panel to sense an external input. The input sensing unit is disposed on the display panel and senses a user's touch as an external input. The input sensing unit includes a plurality of sensing electrodes for sensing an external input and sensing lines connected to the sensing electrodes. The sensing electrodes are disposed in an active area and sensing lines are disposed in an inactive area around the active area.

A driving signal is applied to the sensing electrodes, and a change in capacitance of the sensing electrodes is output as a sensing signal. The driving signal is applied to the sensing electrodes through the sensing lines. When a driving signal having a predetermined frequency is applied to the sensing electrodes, electromagnetic waves according to the driving signal may be emitted as unnecessary electromagnetic signals.

Such an electromagnetic signal may act as noise to other devices, and may interfere with the operation of other devices. This phenomenon may be defined as electromagnetic interference (EMI). There is a need to develop a technology capable of reducing electromagnetic interference.

### SUMMARY

Embodiments of the present disclosure provide a display device with improved sensing performance.

According to an embodiment, a display device includes a display panel that displays an image, an input sensor disposed on the display panel and including a sensing area and a sensing peripheral area, and a sensor controller that drives the sensing area, wherein the input sensor includes a plurality of sensing electrodes arranged in a first direction and a second direction perpendicular to the first direction, and an auxiliary unit disposed at one side of at least one of the sensing electrodes, wherein a main sensing electrode among the sensing electrodes receives a main sensing signal from the sensor controller, a peripheral sensing electrode adjacent to the main sensing electrode among the sensing electrodes receives a peripheral sensing signal from the sensor controller, and the auxiliary unit receives an auxiliary transmission signal from the sensor controller, the auxiliary transmission signal having an inverted phase from the peripheral sensing signal.

The auxiliary unit may include a plurality of auxiliary electrodes arranged in the second direction, and an auxiliary line electrically connected to the auxiliary electrode.

The auxiliary electrodes may be disposed at one side of the sensing electrodes and correspond to the sensing electrodes.

Each of the auxiliary electrodes may be connected to the auxiliary line, and the auxiliary electrodes may receive the same auxiliary transmission signal from the auxiliary line.

The auxiliary line may include a plurality of auxiliary lines, and each of the auxiliary electrodes may receive the auxiliary transmission signal from the plurality of auxiliary lines connected to each of the auxiliary electrodes.

The auxiliary electrodes may be integrally connected.

The sensing electrode and the auxiliary electrodes corresponding to the sensing electrodes may be electrically insulated from one another.

An amplitude of the peripheral sensing signal may be equal to an amplitude of the auxiliary transmission signal.

The input sensor may further include a plurality of sensing lines connected to each of the sensor controller and the sensing electrodes, and the sensing lines connected to the sensing electrodes may be disposed on another side opposite to one side of the sensing electrodes in the first direction.

The sensing electrodes, the sensing lines and the auxiliary unit may be disposed on a same layer.

The sensing electrodes may be disposed between the sensing lines and the auxiliary unit.

An area where the sensing electrodes are disposed may be defined as a first area, an area where the auxiliary electrodes may be disposed is defined as a second area, an area where the sensing lines are disposed may be defined as a third area, and each of the first area, the second area and the third area may be included in the sensing area.

The first area may include a plurality of first areas, and the first areas may have a same size.

Distances between the first areas arranged in the first direction may be equal to each other.

At least one of the auxiliary unit or the sensing lines may be disposed between the first areas arranged in the first direction.

A size of the second area may gradually decrease with decreasing distance to the sensor controller.

A size of the third area may gradually increase with decreasing distance to the sensor controller.

The second area includes a plurality of second areas, and the second areas disposed in the first direction may have a constant size.

The sensing electrodes may further include a reference sensing electrode adjacent to the peripheral sensing electrode.

The reference sensing electrode may receive a reference signal from the sensor controller.

The input sensor of the present disclosure includes a sensing electrode and an auxiliary electrode corresponding to the sensing electrode. An auxiliary transmission signal having an opposite phase to a sensing signal may be applied to the auxiliary electrode corresponding to the sensing electrode driven by the sensing signal, so that the electromagnetic signal generated by the input sensor is canceled by the auxiliary transmission signal. Therefore, operation reliability of the input sensor may be improved.

### BRIEF DESCRIPTION OF THE FIGURES

The above and other objects and features of the present disclosure will become apparent by describing in detail embodiments thereof with reference to the accompanying drawings:

FIG. 1 is a perspective view illustrating a display device according to an embodiment of the present disclosure;

FIG. 2 is an exploded perspective view illustrating a display device according to an embodiment of the present disclosure;

FIG. 3 is a cross-sectional view of a display device taken along line I-I′ of FIG. 2;

FIG. 4 is a plan view of a display panel according to an embodiment of the present disclosure;

FIG. 5 is a plan view illustrating a portion of a display panel corresponding to an area AA′ of FIG. 4;

FIG. 6 is a cross-sectional view of a portion of the display module corresponding to line II-II′ of FIG. 2;

FIG. 7A is a plan view illustrating an input sensor according to an embodiment of the present disclosure;

FIG. 7B is an enlarged view illustrating a portion of an input sensor according to an embodiment of the present disclosure;

FIG. 8 is an enlarged view illustrating a portion corresponding to an area BB′ of FIG. 7A;

FIG. 9 is an enlarged view illustrating a portion corresponding to a portion of the sensing electrode and a portion of the auxiliary unit of FIG. 7A;

FIG. 10 is an enlarged view illustrating a portion corresponding to an area CC′ of FIG. 7A;

FIG. 11A is a diagram illustrating transmission signals applied to the sensing electrodes shown in FIG. 10;

FIG. 11B is a diagram illustrating transmission signals applied to the auxiliary electrodes shown in FIG. 10;

FIG. 12A is a plan view illustrating a portion of an input sensor according to an embodiment of the present disclosure; and

FIG. 12B is a plan view illustrating a portion of an input sensor according to an embodiment of the present disclosure.

### DETAILED DESCRIPTION

The embodiments of the present disclosure may be variously modified and have various forms. Specific embodiments are illustrated in the drawings and described in detail in following descriptions. However, it should be understood that this is not intended to limit the present disclosure to specific disclosed forms, and includes all modifications, equivalents, and substitutes included in the spirit and scope of the present disclosure.

In the present specification, when it is mentioned that a certain component (or an area, a layer, a portion, and the like) is “placed on”, “connected to”, or “coupled to” another component“, it means that the component may be disposed/connected/coupled directly on/to another component or that a third component may be interposed therebetween.

Like reference numerals refer to like elements. In addition, the thicknesses of the lines and the sizes of the components shown in the drawings may be exaggerated for clarity and convenience of explanation.

The term “and/or” includes one combination or more that may define the associated elements.

The terms “first,”“second,” etc. may be used to describe various elements, but the elements should not be limited by the terms. The terms may be referred to as a second component only for the purpose of distinguishing one component from another component, for example without departing from the scope of the right according to the concept of the present disclosure. Similarly, the second component may also be referred to as a first component. Singular forms are intended to include plural forms unless the context clearly indicates otherwise.

In addition, terms such as “below”, “lower side”, “above”, “upper side”, and the like are used to describe the relationship between components shown in the drawings. The above terms are relative concepts and will be described based on the directions shown in the drawings.

Unless otherwise defined, all terms used herein (including technical or scientific terms) have the same meanings as those generally understood by a person skilled in the art to which the present disclosure pertains. In addition, the terms defined in the generally used dictionaries should be construed as having the meanings that coincide with the meanings of the contexts of the related technologies, and should not be construed as ideal or excessively formal meanings unless clearly defined in the specification of the present disclosure.

In the present disclosure, terms such as “include” and/or “have” may be construed to denote a certain characteristic, number, step, operation, constituent element, component or a combination thereof, but may not be construed to exclude the existence of or a possibility of addition of one or more other characteristics, numbers, steps, operations, constituent elements, components or combinations thereof.

Hereinafter, embodiments of the present disclosure will be described with reference to the drawings.

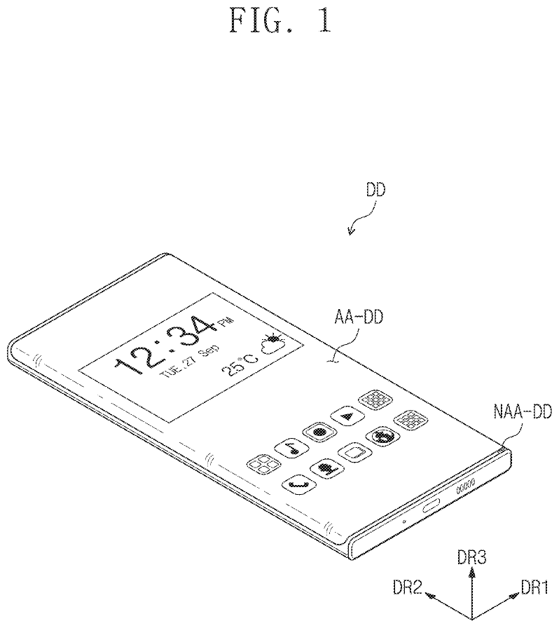

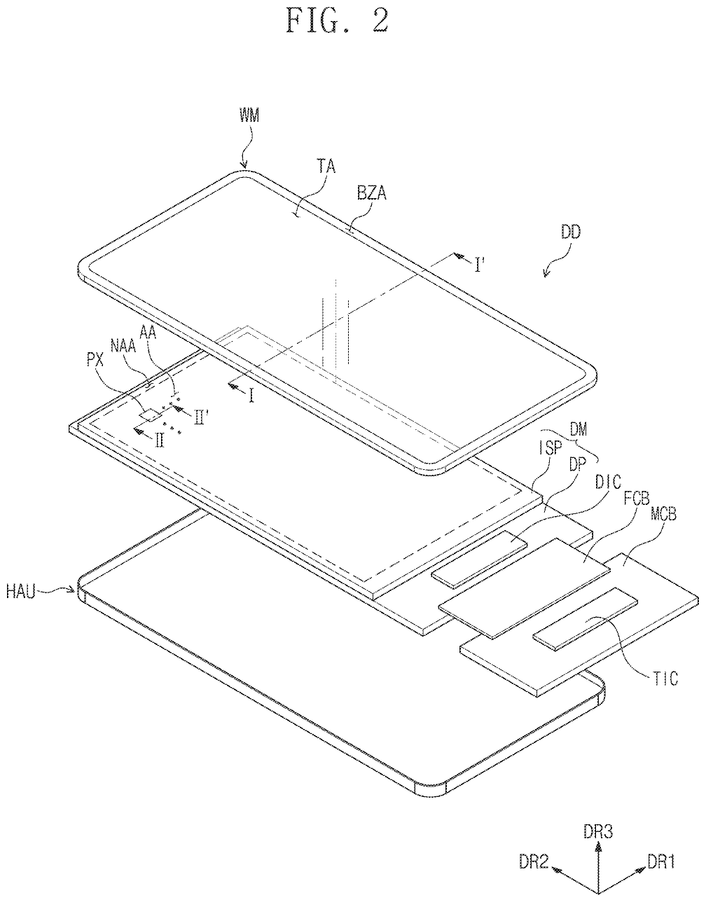

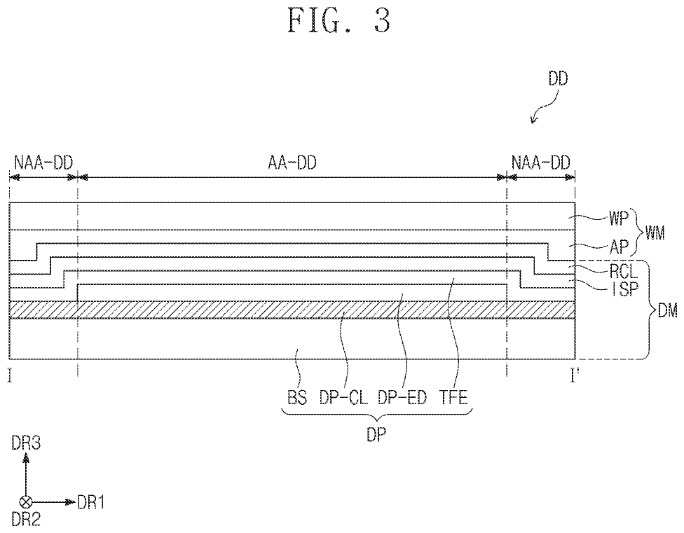

FIG. 1 is a perspective view illustrating a display device according to an embodiment of the present disclosure. FIG. 2 is an exploded perspective view illustrating a display device according to an embodiment of the present disclosure. FIG. 3 is a cross-sectional view of a display device taken along line I-I′ of FIG. 2.

A display device DD according to an embodiment of the present disclosure shown in FIGS. 1 to 3 may be a device activated according to an electrical signal. For example, the display device DD may be a mobile phone, a tablet, a vehicle navigation system, a game console, or a wearable device, but the embodiment is not limited thereto. FIG. 1 illustrates that the display device DD is a mobile phone.

The display device DD according to an embodiment of the present disclosure may display an image through an active area AA-DD. The active area AA-DD may include a plane defined by a first direction DR1 and a second direction DR2. The active area AA-DD may further include a curved surface bent from at least one side of the plane defined by the first direction DR1 and the second direction DR2. FIG. 1 illustrates the display device DD including two curved surfaces each bent from both sides of the plane defined by the first and second directions DR1 and DR2. However, the shape of the active area AA-DD is not limited thereto. For example, the active area AA-DD may include only the plane, and the active area AA-DD may include at least two or more curved surfaces of the plane, for example, each one of the four curved surfaces may extend along one of the four sides of the display device DD.

A peripheral area NAA-DD is adjacent to the active area AA-DD. The peripheral area NAA-DD may surround the active area AA-DD. Accordingly, the shape of the active area AA-DD may be substantially defined by the peripheral area NAA-DD. However, this is shown as an example, and the peripheral area NAA-DD may be disposed adjacent to only one side of the active area AA-DD or may be omitted. The display device DD according to an embodiment of the present disclosure may include active areas having various shapes, and is not limited to one embodiment.

Meanwhile, in FIG. 1 and the following drawings, the first to third directions DR1 to DR3 are illustrated, and the directions indicated by the first to third directions DR1, DR2 and DR3 described herein, which are relative, may be transformed into other directions. In addition, the directions indicated by the first to third directions DR1, DR2 and DR3 may be described as the first to third directions, and the same reference numerals may be used. In the present disclosure, the first direction DR1 and the second direction DR2 are orthogonal to each other, and the third direction DR3 is a normal direction to the plane defined by the first and second directions DR1 and DR2.

The thickness direction of the display device DD may be parallel to the third direction DR3, which is a normal direction to the plane defined by the first and second directions DR1 and DR2. In this specification, the front surfaces (or upper surfaces) and the rear surfaces (or lower surfaces) of the members constituting the display device DD may be defined based on the third direction DR3.

The display device DD may include a display module DM. The display module DM may be a component that generates an image and detects an input applied from an outside. The display module DM may include a display panel DP and an input sensor ISP disposed on the display panel DP. In addition, the display module DM according to an embodiment of the present disclosure may further include an optical layer RCL disposed on the input sensor ISP.

An active area AA and a peripheral area NAA may be defined in the display module DM. The active area AA may be an area activated according to an electrical signal. The peripheral area NAA may be an area located adjacent to at least one side of the active area AA.

The active area AA may correspond to the active area AA-DD of the display device DD shown in FIG. 1. The peripheral area NAA may be disposed to surround the active area AA. However, the embodiment is not limited thereto, and unlike that shown in FIG. 2, in an embodiment, some of the peripheral area NAA may be omitted. A driving circuit or driving line for driving the active area AA may be disposed in the peripheral area NAA.

A plurality of pixels PX may be disposed in the active area AA of the display module DM. The plurality of pixels PX may include red pixels, green pixels, and blue pixels, and may further include white pixels according to embodiments.

The display panel DP may be configured to substantially generate an image. The display panel DP may be a light emitting display panel. For example, the display panel DP may be an organic light emitting display panel, an inorganic light emitting display panel, a quantum dot display panel, a micro LED display panel, or a nano LED display panel. The display panel DP may be referred to as a display layer.

The display panel DP may include a base layer BS, a circuit layer DP-CL, a light emitting element layer DP-ED, and an encapsulation layer TFE.

The base layer BS may be a member providing a base surface on which the circuit layer DP-CL is disposed. The base layer BS may be a rigid substrate or a flexible substrate capable of being bent, folded, or rolled. The base layer BS may be a glass substrate, a metal substrate, or a polymer substrate. However, the embodiment is not limited thereto, and the base layer BS may be an inorganic layer, an organic layer, or a composite material layer.

The base layer BS may have a multilayer structure. For example, the base layer BS may include a first synthetic resin layer, a multi-layered or single-layered intermediate layer, and a second synthetic resin layer disposed on the intermediate layer. The intermediate layer may be referred to as a base barrier layer. The intermediate layer may include a silicon oxide (SiOx) layer and an amorphous silicon (a-Si) layer disposed on the silicon oxide layer, but is not particularly limited thereto. For example, the intermediate layer may include at least one of a silicon oxide layer, a silicon nitride layer, a silicon oxynitride layer, and an amorphous silicon layer.

Each of the first and second synthetic resin layers may include a polyimide-based resin. In addition, each of the first and second synthetic resin layers may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin. Meanwhile, in the present specification, “˜˜”-based resin means one containing a functional group of “˜˜”.

The circuit layer DP-CL may be disposed on the base layer BS. The circuit layer DP-CL may include an insulating layer, a semiconductor pattern, a conductive pattern, a signal line, and the like. An insulating layer, a semiconductor layer, and a conductive layer are formed on the base layer BS by a scheme such as coating or deposition, and then the insulating layer, the semiconductor layer, and the conductive layer are selectively patterned through a plurality of photolithography processes. Thereafter, a semiconductor pattern, a conductive pattern, and a signal line included in the circuit layer DP-CL may be formed.

The light emitting element layer DP-ED may be disposed on the circuit layer DP-CL. The light emitting element layer DP-ED may include a light emitting element. For example, the light emitting element layer DP-ED may include an organic light emitting material, an inorganic light emitting material, an organic-inorganic light emitting material, a quantum dot, a quantum rod, a micro LED, or a nano LED.

The encapsulation layer TFE may be disposed on the light emitting element layer DP-ED. The encapsulation layer TFE may protect the light emitting element layer DP-ED from foreign substances such as moisture, oxygen, and dust particles.

The input sensor ISP may be disposed on the display panel DP. The input sensor ISP may detect an external input applied from an outside. The external input may be an input of a user. The input of a user may include various types of external inputs, such as a part of the user's body (e.g., a finger), light, heat, a pen/stylus, pressure, and the like.

The input sensor ISP may be formed on the display panel DP through a continuous process. In this case, it may be expressed that the input sensor ISP is directly disposed on the display panel DP. Direct arrangement may mean that no third component is disposed between the input sensor ISP and the display panel DP. That is, a separate adhesive member may not be disposed between the input sensor ISP and the display panel DP. Alternatively, the input sensor ISP may be coupled to the display panel DP through an adhesive member. The adhesive member may include a conventional adhesive or a sticking agent.

The optical layer RCL may be disposed on the input sensor ISP. The optical layer RCL may be an antireflection layer that reduces reflectance by external light incident from the outside of the display module DM. The optical layer RCL may be formed on the input sensor ISP through a continuous process. The optical layer RCL may include a polarizing plate or a color filter layer. When the optical layer RCL includes a color filter layer, the color filter layer may include a plurality of color filters disposed in a predetermined arrangement. For example, color filters may be arranged in consideration of emission colors of pixels included in the display panel DP. In addition, the optical layer RCL may further include a black matrix adjacent to the color filters. However, the embodiment is not limited thereto, and in an embodiment, the optical layer RCL may be omitted.

The display device DD may further include a main circuit board MCB, a flexible circuit film FCB and a driving circuit DIC, and a sensor controller TIC. At least one of them may be omitted. Each of the driving circuit DIC and the sensor controller TIC may be provided in the form of an integrated chip. The main circuit board MCB may be connected to the flexible circuit film FCB and electrically connected to the display panel DP. The main circuit board MCB may include a plurality of driving elements. The flexible circuit film FCB is connected to the display panel DP to electrically connect the display panel DP and the main circuit board MCB. The display panel DP may be bent such that the flexible circuit film FCB and the main circuit board MCB face the rear surface of the display device DD.

Although FIG. 2 illustrates the driving circuit DIC mounted on the display panel DP as an example, the driving circuit DIC may be mounted on the flexible circuit film FCB. The driving circuit DIC may include driving elements for driving pixels of the display panel DP, for example, a data driving circuit.

Although not shown, the input sensor ISP may be electrically connected to the main circuit board MCB through an additional flexible circuit film. However, embodiments of the present disclosure are not limited thereto. The input sensor ISP may be electrically connected to the display panel DP and may be electrically connected to the main circuit board MCB through the flexible circuit film FCB.

The display device DD may include a window WM disposed on the display module DM. The window WM may cover the entire outer side of the display module DM. The window WM may have a shape corresponding to that of the display module DM. The window WM according to an embodiment of the present disclosure may include an optically transparent insulating material. The window WM may be a glass substrate or a polymer substrate. For example, the window WM may be a tempered glass substrate.

The display device DD may include a housing HAU containing the display module DM and the like. The housing HAU may be coupled to the window WM.

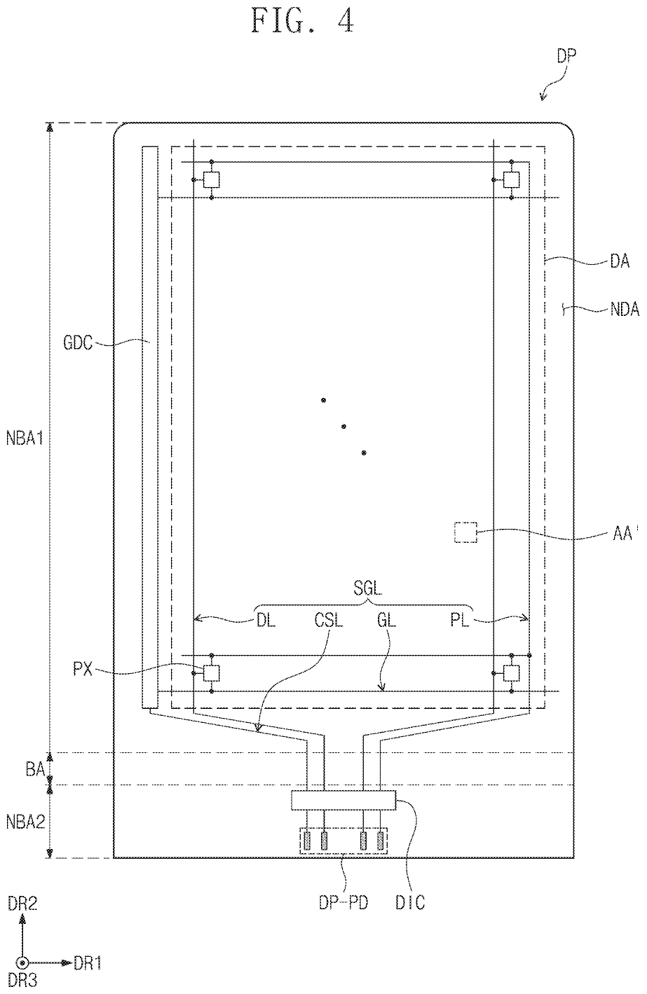

FIG. 4 is a plan view of a display panel according to an embodiment of the present disclosure.

Referring to FIG. 4, the display panel DP may be divided into a display area DA and a non-display area NDA on a plane. The display area DA of the display panel DP may be an area where an image is displayed, and the non-display area NDA may be an area where a driving circuit or driving line is disposed. Light emitting elements of each of the plurality of pixels PX may be disposed in the display area DA. The display area DA and the non-display area NDA of the display panel DP may correspond to the active area AA-DD and the peripheral area NAA-DD of the display device DD shown in FIG. 1, respectively.

According to an embodiment of the present disclosure, the display panel DP may include the plurality of pixels PX, a plurality of signal lines SGL, a scan driving circuit GDC, the driving circuit DIC, and a display pad unit DP-PD.

Each of the pixels PX may include a light emitting element and a plurality of transistors connected thereto. The pixels PX may emit light corresponding to an applied electrical signal.

The signal lines SGL may include scan lines GL, data lines DL, a power line PL, and a control signal line CSL. The scan lines GL may be connected to a corresponding pixel PX among the pixels PX, respectively. The data lines DL may be connected to a corresponding pixel PX among the pixels PX, respectively. The power line PL may be connected to the pixels PX to provide a power voltage. The control signal line CSL may provide control signals to the scan driving circuit GDC.

The scan driving circuit GDC may be disposed in the non-display area NDA. The scan driving circuit GDC may generate scan signals and sequentially output the scan signals to the scan lines GL. The scan driving circuit GDC may further output another control signal to the driving circuit of the pixels PX.

The scan driving circuit GDC may include a plurality of thin film transistors formed through the same process as the driving circuit of the pixels PX, for example, a low-temperature polycrystalline silicon (LTPS) process or a low-temperature polycrystalline oxide (LTPO) process.

In the display panel DP according to an embodiment, a partial area of the display panel DP may be bent. The display panel DP may include a first non-bending area NBA1, a second non-bending area NBA2 spaced apart from the first non-bending area NBA1 in the first direction DR1, and a bending area BA defined between the first non-bending area NBA1 and the second non-bending area NBA2. The first non-bending area NBA1 may include the display area DA and a part of the non-display area NDA. The non-display area NDA may include a bending area BA and the second non-bending area NBA2.

The bending area BA may be bent along a virtual axis extending in the first direction DR1. When the bending area BA is bent, the second non-bending area NBA2 may face the first non-bending area NBA1. Although not shown, in the display panel DP according to an embodiment, the width of the first non-bending area NBA1 in the first direction DR1 may be smaller than the width of the bending area BA in the first direction DR1.

The display pad unit DP-PD may be disposed adjacent to an end of the second non-bending area NBA2. The signal lines SGL may extend from the first non-bending area NBA1 to the second non-bending area NBA2 via the bending area BA and be connected to the display pad unit DP-PD. The flexible circuit film (FCB, see FIG. 1B) may be electrically connected to the display pad unit DP-PD. As the flexible circuit film (FCB, see FIG. 1B) is attached to the display pad unit DP-PD through a conductive adhesive film or the like, the display panel DP and the flexible circuit film (FCB, see FIG. 2) may be electrically connected. Meanwhile, the driving circuit DIC may be mounted on the display panel DP and may include a data driving circuit.

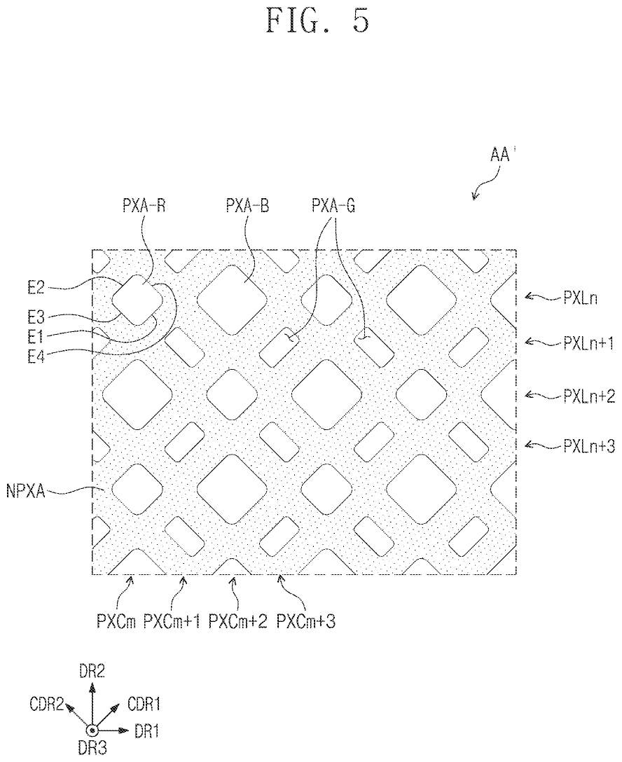

FIG. 5 is a plan view illustrating a portion of a display panel corresponding to an area AA′ of FIG. 4.

Referring to FIGS. 4 and 5, a plurality of light-emitting areas PXA-R, PXA-G, and PXA-B and a non-emission area NPXA disposed between the plurality of light-emitting areas PXA-R, PXA-G, and PXA-B may be included in the display area DA of the display panel DP.

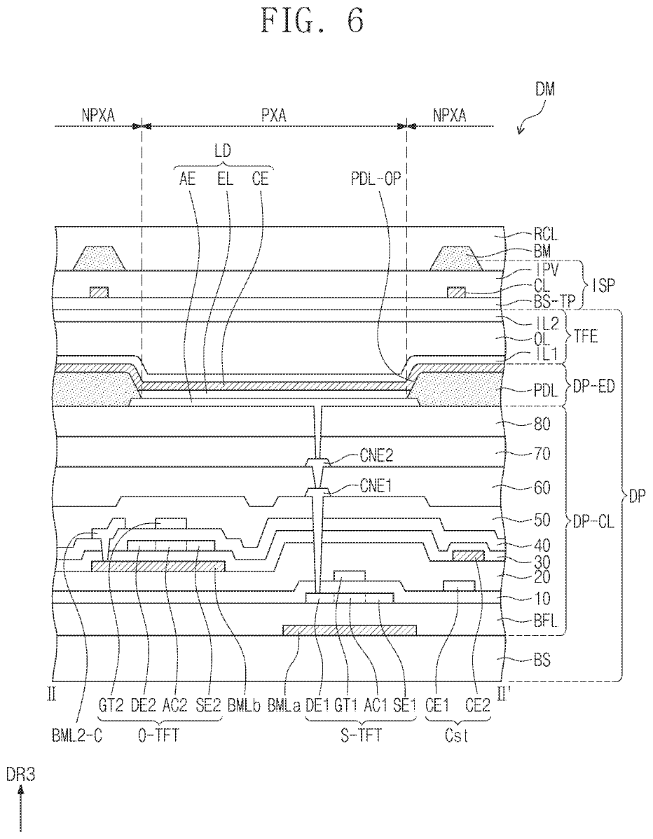

The plurality of light-emitting areas PXA-R, PXA-G, and PXA-B may be divided into the first color light emitting area PXA-R, the second color light emitting area PXA-G, and the third color light emitting area. PXA-B. The first color light emitting area PXA-R, the second color light emitting area PXA-G, and the third color light emitting area PXA-B may be distinguished from each other according to the color of the source light generated from a light emitting element LD (FIG. 6).

Areas of the first color light emitting area PXA-R, the second color light emitting area PXA-G, and the third color light emitting area PXA-B may be different from each other. However, the embodiment is not limited thereto, and at least one of the areas of the first color light emitting area PXA-R, the second color light emitting area PXA-G, and the third color light emitting area PXA-B may be different from the others. In this embodiment, the first color may be red, the second color may be green, and the third color may be blue. Alternatively, the display panel DP may include three groups of light emitting areas displaying three main colors of yellow, magenta, and cyan.

Each of the first color light emitting area PXA-R, the second color light emitting area PXA-G, and the third color light emitting area PXA-B may have a “substantially polygonal shape”. In this case, “a substantially polygonal image includes a polygon in a mathematical sense and a polygon in which curves are defined at vertices”. The shape of the light emitting area may correspond to the shape of a pixel opening PDL-OP (FIG. 6) formed in a pixel defining layer, and the shape of the vertex may vary depending on the etching performance of the pixel defining layer.

In the present embodiment, the first color light emitting area PXA-R having a square shape, the third color light emitting area PXA-B having a square shape, and the second color light emitting area PXA-G having a rectangular shape are illustrated. The second color light emitting area PXA-G may include two types of second color light emitting areas PXA-G having long sides of which extension directions are different from each other.

Each of the first color light emitting area PXA-R, the second color light emitting area PXA-G, and the third color light emitting area PXA-B includes a first edge E1 to a fourth edge E4. The first edge E1 and the second edge E2 may extend in a first diagonal direction CDR1 intersecting the first and second directions DR1 and DR2, and are spaced apart while a corresponding light emitting area is interposed therebetween. The third edge E3 and the fourth edge E4 may extend in a second diagonal direction CDR2 intersecting the first direction DR1, the second direction DR2, and the first diagonal direction CDR1, and spaced apart while a corresponding light emitting area is interposed therebetween.

The plurality of light emitting areas PXA-B, PXA-R, and PXA-G may define a plurality of light emitting rows arranged in the second direction DR2. The light emitting rows may include an n-th light emitting row PXLn (where ‘n’ is an integer greater than or equal to ‘1’), an (n+1)-th light emitting row PXLn+1, an (n+2)-th light emitting row PXLn+2, and an (n+3)-th light emitting row PXLn+3. The foulight emitting rows PXLn, PXLn+1, PXLn+2 and PXLn+3 may form a unit and may be repeatedly arranged in the second direction DR2. Each of the four light emitting rows PXLn, PXLn+1, PXLn+2 and PXLn+3 may extend in the first direction DR1.

The n-th light emitting row PXLn includes the first color light emitting areas PXA-R and the third color light emitting areas PXA-B alternately disposed in the first direction DR1. The (n+2)-th light emitting row PXLn+2 includes the third color light emitting areas PXA-B and the first color light emitting areas PXA-R alternately disposed in the first direction DR1.

The arrangement order of the light emitting areas of the n-th light emitting row PXLn and the arrangement order of the light emitting areas of the (n+2)-th light emitting row PXLn+2 may be different from each other. The third color light emitting areas PXA-B and the first color light emitting areas PXA-R of the n-th light emitting row PXLn may be alternately arranged with the third color light emitting areas PXA-B and the first color light emitting areas PXA-R of the (n+2)-th light emitting row PXLn+2. The light emitting areas of the n-th light emitting row PXLn may be the same as those shifted in the second direction DR2 by one light emitting area compared to the light emitting areas of the (n+2)-th light emitting row PXLn+2.

The second color light emitting areas PXA-G are disposed in each of the (n+1)-th light emitting row PXLn+1 and the (n+3)-th light emitting row PXLn+3. The light emitting areas of the (n+1)-th light emitting row PXLn+1 may be the same as those shifted in the second direction DR2 by one light emitting area compared to the light emitting areas of the (n+3)-th light emitting row PXLn+3. The light emitting areas of the n-th light emitting row PXLn and the light emitting areas of the (n+1)-th light emitting row PXLn+1 are alternately disposed. The light emitting areas of the (n+2)-th light emitting row PXLn+2 and the light emitting areas of the (n+3)-th light emitting row PXLn+3 may be alternately disposed.

Meanwhile, the plurality of light emitting areas PXA-B, PXA-R, and PXA-G may define a plurality of light emitting columns arranged in the first direction DR1. The light emitting columns may include a m-th light emitting column PXCm, a (m+1)-th light emitting column PXCm+1, a (m+2)-th light emitting column PXCm+2, and a (m+3)-th light emitting column PXCm+3 (where ‘m’ is an integer greater than or equal to ‘1’). The four light emitting columns PXCm, PXCm+1, PXCm+2, and PXCm+3 may form a unit and be repeatedly arranged in the first direction DR1. Each of the four light emitting columns PXCm, PXCm+1, PXCm+2, and PXCm+3 may extend in the second direction DR2.

The configuration of the light emitting areas PXA-B, PXA-R, and PXA-G included in each of the light emitting columns PXCm, PXCm+1, PXCm+2, and PXCm+3 may be determined according to the arrangement of the light emitting areas PXA-B, PXA-R, and PXA-G in the above-described light emitting rows PXLn, PXLn+1, PXLn+2, and PXLn+3. For example, the m-th light emitting column PXCm may include the first color light emitting areas PXA-R and the third color light emitting areas PXA-B alternately disposed in the second direction DR2 and the (m+2)-th light emitting column PXCm+2 may include the third color light emitting areas PXA-B and the first color light emitting areas PXA-R alternately disposed in the second direction DR2. In addition, the second color light emitting areas PXA-G may be disposed in each of the (m+1)-th light emitting column PXCm+1 and the (m+3)-th light emitting column PXCm+3.

The arrangement of the light emitting areas PXA-R, PXA-G, and PXA-B shown in FIG. 5 is exemplary, and the embodiment is not limited thereto. The area of the light emitting areas PXA-R, PXA-G, and PXA-B and the arrangement of the light emitting areas PXA-R, PXA-G, and PXA-B may vary depending on the display quality required of the display device.

FIG. 6 is a cross-sectional view of a portion of the display module corresponding to line II-II′ of FIG. 2.

Referring to FIG. 6, the display panel DP may include a plurality of insulating layers, a semiconductor pattern, a conductive pattern, a signal line, and the like. An insulating layer, a semiconductor layer, and a conductive layer are formed in a scheme such as coating, deposition, or the like. Then, the insulating layer, the semiconductor layer, and the conductive layer may be selectively patterned in a photolithography scheme. In such a manner, a semiconductor pattern, a conductive pattern, a signal line, and the like included in the circuit layer DP-CL and the light emitting element layer DP-ED are formed. Thereafter, the encapsulation layer TFE covering the light emitting element layer DP-ED may be formed.

FIG. 6 illustrates a pixel circuit including the light emitting element LD, and a silicon thin film transistor S-TFT and an oxide thin film transistor O-TFT for driving the light emitting element LD.

A buffer layer BFL may be disposed on the base layer BS. The buffer layer BFL may prevent diffusion of metal atoms or impurities from the base layer BS into the first semiconductor pattern. In addition, the buffer layer BFL may control a heat supply rate during a crystallization process for forming the first semiconductor pattern, such that the first semiconductor pattern is uniformly formed.

A first back metal layer BMLa may be disposed below the silicon thin film transistor S-TFT, and a second back metal layer BMLb may be disposed below the oxide thin film transistor O-TFT. The first and second back metal layers BMLa and BMLb may be disposed overlapped with the silicon thin film transistor S-TFT and the oxide thin film transistor O-TFT to protect the silicon thin film transistor S-TFT and the oxide thin film transistor O-TFT. The first and second back metal layers BMLa and BMLb may prevent the electric potential due to the polarization of the base layer BS from affecting the silicon thin film transistor S-TFT and the oxide thin film transistor O-TFT. The first back metal layer BMLa may be disposed overlapping with the driving thin film transistor provided as the silicon thin film transistor S-TFT.

The first back metal layer BMLa may be disposed between the base layer BS and the buffer layer BFL. The first back metal layer BMLa according to an embodiment of the present disclosure may be disposed on the base layer BS which includes organic layers and inorganic layers that are alternately stacked. Alternatively, the first back metal layer BMLa may be disposed within the buffer layer BFL. In this case, an inorganic barrier layer may be further disposed between the first back metal layer BMLa and the buffer layer BFL. The first back metal layer BMLa may be connected to an electrode or a line to receive a constant voltage or a signal therethrough. However, the embodiment is not limited thereto, and the first back metal layer BMLa may be provided in an isolated form from other electrodes or lines.

The second back metal layer BMLb may be disposed to correspond to a lower portion of the oxide thin film transistor O-TFT. The second back metal layer BMLb may be disposed between a second insulating layer 20 and a third insulating layer 30. The second back metal layer BMLb may be disposed on the same layer as a second electrode CE2 of a storage capacitor Cst. The second back metal layer BMLb may be connected to a contact electrode BML2-C to receive a constant voltage or signal. The contact electrode BML2-C may be disposed on the same layer as a gate GT2 of the oxide thin film transistor O-TFT.

Each of the first back metal layer BMLa and the second back metal layer BMLb may include a reflective metal. For example, each of the first back metal layer BMLa and the second back metal layer BMLb may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), titanium (Ti), and p+ doped amorphous silicon. The first back metal layer BMLa and the second back metal layer BMLb may include the same material or different materials.

The first semiconductor pattern may be disposed on the buffer layer BFL. The first semiconductor pattern may include a silicon semiconductor. For example, the silicon semiconductor may include amorphous silicon, polycrystalline silicon, and the like. As an example of the present disclosure, the first semiconductor pattern may include low-temperature polysilicon.

FIG. 6 illustrates a portion of the first semiconductor pattern disposed on the buffer layer BFL, and the first semiconductor pattern may be further disposed in another area. The first semiconductor pattern may be arranged in a specific rule across the pixels. The first semiconductor pattern may have different electrical properties depending on whether the first semiconductor pattern is doped. The first semiconductor pattern may include a first region having high conductivity and a second region having low conductivity. The first region may be doped with an N-type dopant or a P-type dopant. The P-type transistor may include a doped region doped with a P-type dopant, and the N-type transistor may include a doped region doped with an N-type dopant. The second region may be a non-doped region or a region doped at a lower concentration than the first region.

The conductivity of the first region is greater than that of the second region, and the first region may substantially serve as an electrode or a signal line. The second region may substantially correspond to an active region (or channel) of a transistor. In other words, a portion of the semiconductor pattern may be an active region of a transistor, another portion may be a source or drain of a transistor, and still another portion may be a connection electrode or a connection signal line.

A source region SE1, an active portion AC1 and a drain region DE1 of the silicon thin film transistor S-TFT may be formed based on a first semiconductor pattern. The source region SE1 and the drain region DE1 may extend in opposite directions from the active portion AC1 on a cross section.

A first insulating layer 10 may be disposed on the buffer layer BFL. The first insulating layer 10 commonly overlaps the plurality of pixels PX (FIG. 2) and may cover the first semiconductor pattern. The first insulating layer 10 may be an inorganic layer and/or an organic layer, and may have a single-layer or multi-layer structure. The first insulating layer 10 may include at least one of aluminum oxide, titanium oxide, silicon oxide, silicon nitride, silicon oxynitride, zirconium oxide, and hafnium oxide. In the embodiment, the first insulating layer 10 may be a single-layer silicon oxide layer. In addition to the first insulating layer 10, the insulating layer of the circuit layer DP-CL to be described below may be an inorganic layer and/or an organic layer, and may have a single-layer or multi-layer structure. The inorganic layer may include at least one of the above-described materials, but is not limited thereto.

A gate GT1 of the silicon thin film transistor S-TFT is disposed on the first insulating layer 10. The gate GT1 may be a part of a metal pattern. The gate GT1 overlaps the active portion AC1. In a process of doping the first semiconductor pattern, the gate GT1 may function as a mask. The gate GT1 may include titanium (Ti), silver (Ag), an alloy containing silver, molybdenum (Mo), an alloy containing molybdenum, aluminum (Al), an alloy containing aluminum, aluminum nitride (AlN), and tungsten. (W), tungsten nitride (WN), copper (Cu), indium tin oxide (ITO), indium zinc oxide (IZO), and the like, but is not particularly limited thereto.

The second insulating layer 20 is disposed on the first insulating layer 10 and may cover the gate GT1. The second insulating layer 20 may be an inorganic layer and/or an organic layer, and may have a single-layer or multi-layer structure. The second insulating layer 20 may include at least one of silicon oxide, silicon nitride, and silicon oxynitride. In the embodiment, the second insulating layer 20 may have a multi-layer structure including a silicon oxide layer and a silicon nitride layer.

The third insulating layer 30 may be disposed on the second insulating layer 20. The third insulating layer 30 may have a single-layer or multi-layer structure. For example, the third insulating layer 30 may have a multi-layer structure including a silicon oxide layer and a silicon nitride layer. The second electrode CE2 of the storage capacitor Cst may be disposed between the second insulating layer 20 and the third insulating layer 30. In addition, a first electrode CE1 of the storage capacitor Cst may be disposed between the first insulating layer 10 and the second insulating layer 20.

A second semiconductor pattern may be disposed on the third insulating layer 30. The second semiconductor pattern may include an oxide semiconductor. The oxide semiconductor may include a plurality of regions classified according to whether the metal oxide is reduced. A region where the metal oxide is reduced (hereinafter referred to as a reduced region) has higher conductivity than a region (hereinafter referred to as a non-reduced region) where the metal oxide is not reduced. The reduced region substantially serves as a source/drain of a transistor or a signal line. The non-reduced region substantially corresponds to the active region (or semiconductor region or channel) of the transistor. In other words, a portion of the second semiconductor pattern may be an active region of a transistor, another portion may be a source/drain region of a transistor, and still another portion may be a signal transmission region.

A source region SE2, an active portion AC2, and a drain region DE2 of the oxide thin film transistor O-TFT may be formed from the second semiconductor pattern. The source region SE2 and the drain region DE2 may extend in opposite directions from the active portion AC2 on a cross section.

A fourth insulating layer 40 may be disposed on the third insulating layer 30. The fourth insulating layer 40 may commonly overlap the plurality of pixels PX (FIG. 2) and may cover the second semiconductor pattern. The fourth insulating layer 40 may include at least one of aluminum oxide, titanium oxide, silicon oxide, silicon nitride, silicon oxynitride, zirconium oxide, and hafnium oxide.

The gate GT2 of the oxide thin film transistor O-TFT is disposed on the fourth insulating layer 40. The gate GT2 may be a part of the metal pattern. The gate GT2 overlaps the active portion AC2. In a process of doping the second semiconductor pattern, the gate GT2 may function as a mask.

A fifth insulating layer 50 may be disposed on the fourth insulating layer 40 and may cover the gate GT2. The fifth insulating layer 50 may be an inorganic layer and/or an organic layer, and may have a single-layer or multi-layer structure.

A first connection electrode CNE1 may be disposed on the fifth insulating layer 50. The first connection electrode CNE1 is connected to the drain region DE1 of the silicon thin film transistor S-TFT through a contact hole passing through the first to fifth insulating layers 10 to 50. FIG. 6 illustrates that the first connection electrode CNE1 is directly connected to the drain region DE1 of the silicon thin film transistor S-TFT, but the first connection electrode CNE1 is connected to the drain region DE1 through an emission control thin film transistor (not shown).

A sixth insulating layer 60 may be disposed on the fifth insulating layer 50. A second connection electrode CNE2 may be disposed on the sixth insulating layer 60. The second connection electrode CNE2 may be connected to the first connection electrode CNE1 through a contact hole penetrating the sixth insulating layer 60. A seventh insulating layer 70 may be disposed on the sixth insulating layer 60 and may cover the second connection electrode CNE2. An eighth insulating layer 80 may be disposed on the seventh insulating layer 70.

Each of the sixth insulating layer 60, the seventh insulating layer 70 and the eighth insulating layer 80 may be an organic layer. For example, each of the sixth insulating layer 60, the seventh insulating layer 70 and the eighth insulating layer 80 may include benzocyclobutene (BCB), polyimide, hexamethyldisiloxane (HMDSO), or polymethylmethacrylate (PMMA), general-purpose polymers such as polystyrene (PS), a polymer derivative having a phenolic group, acrylic polymer, imide polymer, arylether polymer, amide polymer, fluorine polymer, p-xylene polymer, vinyl alcohol polymer, blends thereof, and the like.

The light emitting element layer DP-ED including the light emitting element LD may be disposed on the circuit layer DP-CL. The light emitting element LD may include a pixel electrode AE, a light emitting layer EL, and a common electrode CE. The pixel electrodes AE may be spaced apart from each other to correspond to each pixel PX (FIG. 2), and the common electrode CE may be commonly provided to the plurality of pixels PX (FIG. 2).

The pixel electrode AE may be disposed on the eighth insulating layer 80. The pixel electrode AE may be formed of a metal material, a metal alloy, or a conductive compound. The pixel electrode AE may be an anode or a cathode. However, the embodiment is not limited thereto. The pixel electrode AE may be a transmissive electrode, a transflective electrode, or a reflective electrode. When the pixel electrode AE is a transmissive electrode, the pixel electrode AE may include a transparent metal oxide such as indium tin oxide (ITO), indium zinc oxide (IZO), zinc oxide (ZnO), indium tin zinc (ITZO), or the like. When the pixel electrode AE is a transflective electrode or a reflective electrode, the pixel electrode AE may include Ag, Mg, Cu, Al, Pt, Pd, Au, Ni, Nd, Ir, Cr, Li, Ca, LiF/Ca, LiF/Al, Mo, Ti, W, or a compound or mixture thereof (e.g., a mixture of Ag and Mg). Alternatively, the pixel electrode AE may be a multi-layer structure including a reflective film or semi-transmissive film formed of the above materials, and a transparent conductive film formed of indium tin oxide (ITO), indium zinc oxide (IZO), zinc oxide (ZnO), indium tin zinc oxide (ITZO), or the like. For example, the pixel electrode AE may have a three-layer structure of ITO/Ag/ITO, but is not limited thereto. In addition, the embodiment is not limited thereto, and the pixel electrode AE may include the above-described metal material, a combination of two or more kinds of metal materials selected from among the above-mentioned metal materials, or an oxide of the above-described metal materials.

A pixel defining layer PDL may be disposed on the eighth insulating layer 80. The pixel defining layer PDL may include a polymer resin. For example, the pixel defining layer PDL may include a polyacrylate-based resin or a polyimide-based resin. In addition, the pixel defining layer PDL may further include an inorganic material in addition to a polymer resin. Meanwhile, the pixel defining layer PDL may include a light absorbing material or may include a black pigment or black dye. The pixel defining layer PDL including black pigment or black dye may implement a black pixel defining layer. When forming the pixel defining layer PDL, carbon black or the like may be used as the black pigment or black dye, but the embodiment is not limited thereto.

In addition, the pixel defining layer PDL may include an inorganic material. For example, the pixel defining layer PDL may include silicon nitride, silicon oxide, or silicon oxynitride.

The pixel defining layer PDL may cover a portion of the pixel electrode AE. For example, the pixel opening PDL-OP exposing a portion of the pixel electrode AE may be defined in the pixel defining layer PDL. The pixel defining layer PDL may increase a distance between the edge of the pixel electrode AE and the common electrode CE. Therefore, an arc or the like may be prevented from occurring at the edge of the pixel electrode AE by the pixel defining layer PDL.

In the display panel DP, light emitting areas PXA may be divided by the pixel defining layer PDL. The display panel DP includes light emitting areas PXA and the non-emission area NPXA, and the non-emission area NPXA may overlap the pixel defining layer PDL. A portion corresponding to the pixel electrode AE exposed through the pixel opening PDL-OP may be defined as the light emitting area PXA.

In the light emitting element LD, the light emitting layer EL may be disposed on the pixel electrode AE. In the embodiment, the light emitting layer EL may emit light of at least one color among blue, red and green.

The common electrode CE may be disposed on the light emitting layer EL. The common electrode CE may have an integral shape and be commonly disposed in the plurality of pixels PX (FIG. 2). The common electrode CE may be a cathode or an anode, but the embodiment is not limited thereto. For example, when the pixel electrode AE is an anode, the common electrode CE may be a cathode, and when the pixel electrode AE is a cathode, the common electrode CE may be an anode.

The common electrode CE may be a transmissive electrode, a transflective electrode, or a reflective electrode. When the common electrode CE is a transmissive electrode, the common electrode CE may include a transparent metal oxide such as indium tin oxide (ITO), indium zinc oxide (IZO), zinc oxide (ZnO), indium tin zinc (ITZO). oxide), or the like. In addition, the common electrode CE may include Ag, Mg, Cu, Al, Pt, Pd, Au, Ni, Nd, Ir, Cr, Li, Ca, LiF/Ca, LiF/Al, Mo, Ti, W, or a compound or mixture thereof (e.g., a mixture of Ag and Mg).

Although not shown, a hole control layer may be disposed between the pixel electrode AE and the light emitting layer EL. The hole control layer may include a hole transport layer and may further include a hole injection layer. An electron control layer may be disposed between the light emitting layer EL and the common electrode CE. The electron control layer may include an electron transport layer and may further include an electron injection layer. The hole control layer and the electron control layer may be commonly formed in the plurality of pixels PX (FIG. 2) by using an open mask.

The encapsulation layer TFE may be disposed on the light emitting element layer DP-ED. The encapsulation layer TFE may include a first inorganic layer IL1, an organic layer OL, and a second inorganic layer IL2 sequentially stacked, but the layers constituting the encapsulation layer TFE are not limited thereto.

The first and second inorganic layers IL1 and IL2 may protect the light emitting element layer DP-ED from moisture and oxygen, and the organic layer OL may protect the light emitting element layer DP-ED from foreign substances such as dust particles. The first and second inorganic layers IL1 and IL2 may include at least one of silicon nitride, silicon oxynitride, silicon oxide, titanium oxide, and aluminum oxide. The organic layer OL may include an acryl-based organic material, but is not limited thereto.

The input sensor ISP may be disposed on the display panel DP. The input sensor ISP may be referred to as a sensor layer, an input sensing layer, or an input sensing panel. The input sensor ISP may include a sensing base layer BS-TP, a first conductive layer CL, and a sensing insulation layer IPV. According to an embodiment of the present disclosure, the input sensor ISP may include a single first conductive layer CL without including a second conductive layer.

The sensing base layer BS-TP may be directly disposed on the display panel DP. The sensing base layer BS-TP may be an inorganic layer including at least one of silicon nitride, silicon oxynitride, and silicon oxide. Alternatively, the sensing base layer BS-TP may be an organic layer including an epoxy-based resin, an acrylic-based resin, or an imide-based resin. The sensing base layer BS-TP may have a single-layer structure or a multi-layer structure stacked in the third direction DR3.

The first conductive layer CL may have a single-layer structure or a multi-layer structure stacked in the third direction DR3.

The conductive layer of the single layer structure may include a metal layer or a transparent conductive layer. The metal layer may include molybdenum, silver, titanium, copper, aluminum, or an alloy thereof. The transparent conductive layer may include a transparent conductive oxide such as indium tin oxide (ITO), indium zinc oxide (IZO), or indium zinc tin oxide (IZTO). In addition, the transparent conductive layer may include a conductive polymer such as PEDOT, a metal nanowire, a graphene, and the like.

The conductive layer of the multi-layer structure may include metal layers. For example, the metal layers may have a three-layer structure of titanium/aluminum/titanium. The conductive layer of the multi-layer structure may include at least one metal layer and at least one transparent conductive layer.

The sensing insulation layer IPV may be disposed on the first conductive layer CL. The sensing insulation layer IPV may include an inorganic layer. The inorganic layer may include at least one of aluminum oxide, titanium oxide, silicon oxide, silicon nitride, silicon oxynitride, zirconium oxide, and hafnium oxide.

Alternatively, the sensing insulation layer IPV may include an organic film. The organic film may include at least one of an acrylic resin, a methacrylic resin, a polyisoprene resin, a vinyl resin, an epoxy resin, a urethane resin, a cellulose resin, a siloxane resin, a polyimide resin, a polyamide resin, and a perylene resin.

Although not shown, the input sensor ISP may further include a second conductive layer disposed on the first conductive layer CL in addition to the first conductive layer CL. When the input sensor ISP further includes the second conductive layer, the sensing insulation layer IPV may be disposed between the first conductive layer CL and the second conductive layer.

The optical layer RCL may be disposed on the input sensor ISP. For example, the optical layer RCL may be formed on the input sensor ISP through a continuous process. However, the embodiment is not limited thereto.

The optical layer RCL may be formed by including a pigment or a fuel. In addition, although not shown, the optical layer RCL may include a plurality of filter units for transmitting light of different wavelength regions. Each of the filter units transmitting light of different wavelength regions may be disposed to correspond to each of the light emitting areas PXA distinguished from the non-emission area areas NPXA.

The optical layer RCL may further include a division pattern BM. A material constituting the division pattern BM is not particularly limited as long as it is a material that absorbs light. The division pattern BM may be a layer having a black color, and the division pattern BM may include a black coloring agent. The black coloring agent may include black dye and black pigment. The black coloring agent may include carbon black, a metal such as chromium, or an oxide thereof.

The division pattern BM may overlap the first conductive layer CL of the input sensor ISP. The division pattern BM may prevent reflection of external light by the first conductive layer CL.

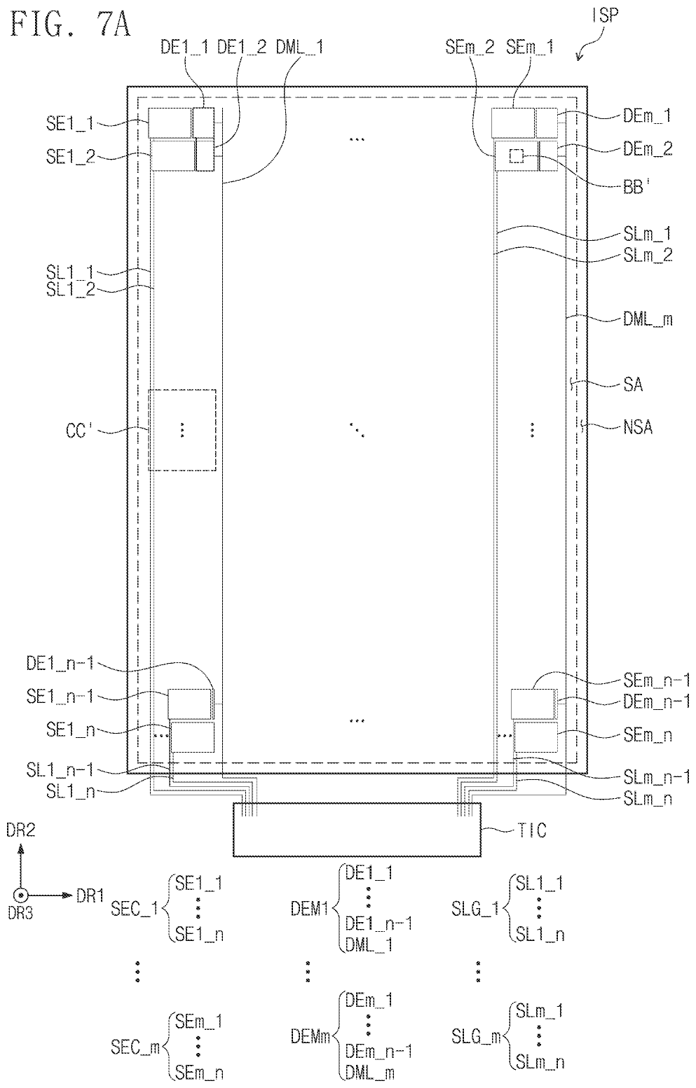

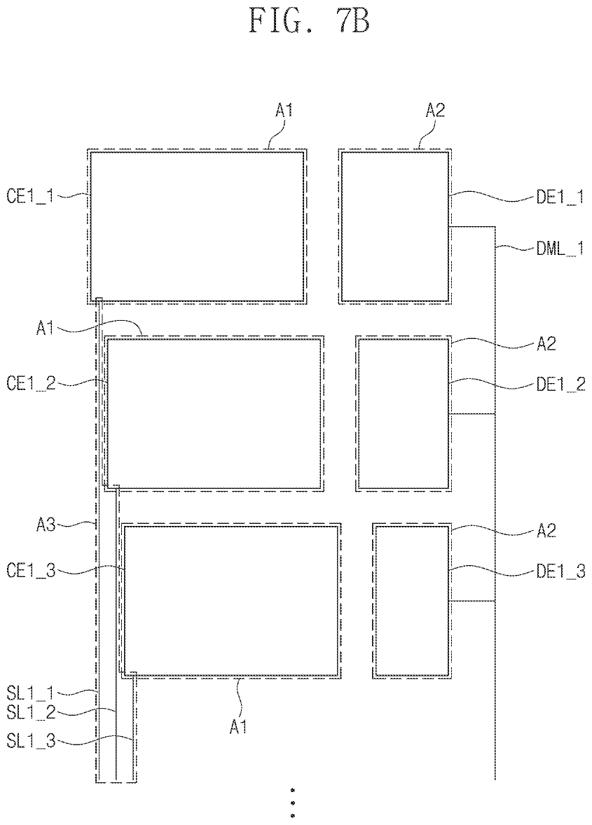

FIG. 7A is a plan view illustrating an input sensor according to an embodiment of the present disclosure. FIG. 7B is an enlarged view illustrating a portion of an input sensor according to an embodiment of the present disclosure.

Referring to FIG. 7A, the input sensor ISP may include a sensing area SA corresponding to the active area AA of the display module DM shown in FIG. 2 and a sensing peripheral area NSA corresponding to the peripheral area NAA. The sensing area SA and the sensing peripheral rea NSA are mutually exclusive.

The sensing area SA may be a part capable of sensing an external input applied from an outside. The external input may include various types of inputs provided from an outside of the input sensor ISP. For example, the external input may include an external input (e.g., hovering) applied close or adjacent to the input sensor ISP at a specified distance as well as a contact by an object—e.g., part of the user's body such as a user's hand or finger, a stylus. In addition, the external input may have various forms such as force, pressure, temperature, light, and the like.

The sensing peripheral area NSA may be a non-sensing area in which an external input is not detected. The sensing peripheral area NSA may correspond to the peripheral area NAA (refer to FIG. 2) and may be a part in which an external input is not detected because sensing electrodes SP are not disposed.

The input sensor ISP may include a plurality of sensing electrodes SE1_1 to SEm_n, a plurality of auxiliary units DEM1 to DEMm, and a plurality of sensing lines SL1_1 to SLm_n. The plurality of sensing electrodes SE1_1 to SEm_n, the plurality of auxiliary units DEM1 to DEMm, and the plurality of sensing lines SL1_1 to SLm_n may be disposed on the same layer.

Each of the plurality of sensing electrodes SE1_1 to SEm_n may have unique coordinate information. The plurality of sensing electrodes SE1_1 to SEm_n may be arranged in a matrix form in the sensing area SA in the first and second directions DR1 and DR2. When the first direction DR1 is defined as a row direction and the second direction DR2 is defined as a column direction, the group of the plurality of sensing electrodes SE1_1 to SEm_n disposed in the same column may be defined as sensing electrode column SEC_1 to SEC_m. That is, a plurality of sensing electrode columns SEC_1 to SEC_m may be disposed in the sensing area SA, and each of the sensing electrode columns SEC_1 to SEC_m may include the plurality of sensing electrodes SE1_1 to SEm_n arranged in the second direction DR2. For example, the first sensing electrode column SEC_1 may include the sensing electrodes SE1_1 to SE1_n arranged in the second direction DR2. FIG. 7A illustrates that m sensing electrode columns SEC_1 to SEC_m arranged in the first direction DR1 are disposed in the sensing area SA, and n sensing electrodes SE1_1 to SEm_n arranged in the second direction DR2 are included in each sensing electrode column, this is exemplary, and the arrangement type and number of sensing electrodes SE1_1 to SEm_n disposed in the sensing area SA are not particularly limited.

Each of the sensing electrodes SE1_1 to SEm_n may have a polygonal shape. FIG. 7A illustrates that each of the sensing electrodes SE1_1 to SEm_n has a square shape, but the shape of each of the sensing electrodes SE1_1 to SEm_n is not particularly limited. According to an embodiment of the present disclosure, the sensing electrodes SE1_1 to SEm_n may all have the same size. All of the sensing electrodes SE1_1 to SEm_n have the same size, but the sensing electrodes SE1_1 to SEm_n arranged in the second direction DR2 may be shifted to the first direction DR1. “Size” of an element (e.g., an electrode), as used herein, refers to the area occupied by the element in the plane defined by the first direction DR1 and the second direction DR2.

The sensing lines SL1_1 to SLm_n may be electrically connected to the sensing electrodes SE1_1 to SEm_n corresponding to the sensing electrodes SE1_1 to SEm_n. In detail, each of the sensing lines SL1_1 to SLm_n may be connected to each of the sensing electrodes SE1_1 to SEm_n to electrically connect each of the sensing electrodes SE1_1 to SEm_n to the sensor controller TIC. The sensing lines SL1_1 to SLm_n may be grouped in a number corresponding to the number of sensing electrode columns SEC_1 to SEC_m. That is, the sensing lines SL1_1 to SLm_n may be grouped into line groups SLG_1 to SLG_m corresponding to the sensing electrode columns SEC_1 to SEC_m. Each line group SLG_1 to SLG_m may include the sensing lines SL1_1 to SLm_n, the number of which corresponds to the number of sensing electrodes SE1_1 to SEm_n included in the sensing electrode columns SEC_1 to SEC_m. For example, the first line group SLG_1 may include the sensing lines SL1_1 to SL1_n extending in the second direction DR2 and arranged in the first direction DR1.

The sensing lines SL1_1 to SLm_n may not overlap with the sensing electrodes SE1_1 to SE1_n. In detail, because the sensing lines SL1_1 to SLm_n are connected to the sensing electrodes SE1_1 to SE1_n, the sensing lines SL1_1 to SLm_n may not overlap with the sensing electrodes SE1_1 to SE1_n other than the sensing electrodes SE1_1 to SE1_n connected to the sensing lines SL1_1 to SLm_n. Lengths extending in the second direction DR2 of the sensing lines SL1_1 to SLm_n, which are arranged in the first direction DR1 and included in each line group SLG_1 to SLG_m, may be shorter in the arrangement order in the first direction DR1. In detail, the first sensing line SL1_1 included in the first line group SLG_1 is the longest, and the n-th sensing line SL1_n is the shortest. Accordingly, the number of sensing lines SL1_1 to SLm_n adjacent to the sensing electrodes SE1_1 to SEm_n may gradually increase toward the sensor controller TIC, and the size of the area where the sensing lines SL1_1 to SLm_n are formed may gradually increase toward the sensor controller TIC.

The sensing lines SL1_1 to SLm_n may apply a sensing signal to the sensing electrodes SE1_1 to SEm_n connected to the sensing lines SL1_1 to SLm_n. As the sensing electrodes SE1_1 to SEm_n receive a sensing signal, a sensing operation is performed, which will be described in detail later.

The auxiliary units DEM1 to DEMm may include a plurality of auxiliary electrodes DE1_1 to DEm_n−1 and auxiliary lines DML_1 to DML_m electrically connected to the auxiliary electrodes DE1_1 to DEm_n−1. The auxiliary units DEM1 to DEMm may extend in the second direction DR2 and may be aligned in the first direction DR1. Accordingly, the auxiliary units DEM1 to DEMm may correspond to the sensing electrode columns SEC_1 to SEC_m, respectively. For example, the first auxiliary unit DEM1 may include the auxiliary electrodes DE1_1 to DE1_n−1 disposed to correspond to the sensing electrodes SE1_1 to SE1_n−1 included in the first sensing electrode column SEC_1. The auxiliary electrodes DE1_1 to DE1_n−1 may be disposed at one side of the sensing electrodes SE1_1 to SE1_n−1. The first line group SLG_1 may be disposed at an opposite side of the sensing electrodes SE1_1 to SE1_n−1.

In addition, the auxiliary electrodes DE1_1 to DE1_n−1 may be disposed at one side of the sensing electrodes SE1_1 to SE1_n−1 in the first direction DR1 with respect to the sensing electrodes SE1_1 to SE1_n−1. The sensing lines SL1_1 to SL1_n included in the first line group SLG_1 may be disposed at an opposite side of the sensing electrodes SE1_1 to SE1_n−1 in the first direction DR1 with reference to the sensing electrodes SE1_1 to SE1_n−1. However, the embodiment is not limited thereto, and the positions of the auxiliary electrodes DE1_1 to DE1_n−1 and the sensing lines SL1_1 to SL1_n may be changed relative to the sensing electrodes SE1_1 to SE1_n−1. As the auxiliary electrodes DE1_1 to DE1_n−1 are disposed at one side of the sensing electrodes SE1_1 to SE1_n and the sensing lines SL1_1 to SL1_n are disposed at an opposite side of the sensing electrodes SE1_1 to SE1_n, each of the sensing electrodes SE1_1 to SE1_n may be disposed between the sensing lines SL1_1 to SL1_n and the auxiliary units DEM1 to DEMm. The same description may be applied to the second to m-th sensing electrode columns SEC_2 to SEC_m.

The sizes of the auxiliary electrodes DE1_1 to DEm_n−1 may vary in the second direction DR2. In detail, the sizes of the auxiliary electrodes DE1_1 to DEm_n−1 may gradually decrease with decreasing distance to the sensor controller TIC. For example, the sizes of the auxiliary electrodes DE1_1 to DE1_n−1 included in the first auxiliary unit DEM1 decrease in the order in which the auxiliary electrodes DE1_1 to DE1_n−1 are arranged in a negative direction in the second direction DR2. The height of each of the auxiliary electrodes DE1_1 to DE1_n−1 in the second direction DR2 is constant, and the width in the first direction DR1 is reduced with increasing proximity to the sensor controller TIC. In an embodiment, the first auxiliary electrode DE1_1 included in the first auxiliary unit DEM1 is the largest, and the n-th auxiliary electrode DE1_n−1 is the smallest. Corresponding to the shift to the first direction DR1 of the sensing electrodes SE1_1 to SE1_n arranged in the second direction DR2, it is possible to determine the widths, that is, sizes, of the auxiliary electrodes DE1_1 to DE1_n−1.

According to an embodiment of the present disclosure, the auxiliary electrodes DE1_1 to DEm_n−1 may be spaced apart from the sensing electrodes SE1_1 to SEm_n and may not be electrically connected to the sensing electrodes SE1_1 to SEm_n. In detail, each of the auxiliary electrodes DE1_1 to DEm_n−1 may be spaced apart from and electrically insulated from a corresponding sensing electrode among the sensing electrodes SE1_1 to SEm_n in the first direction DR1.

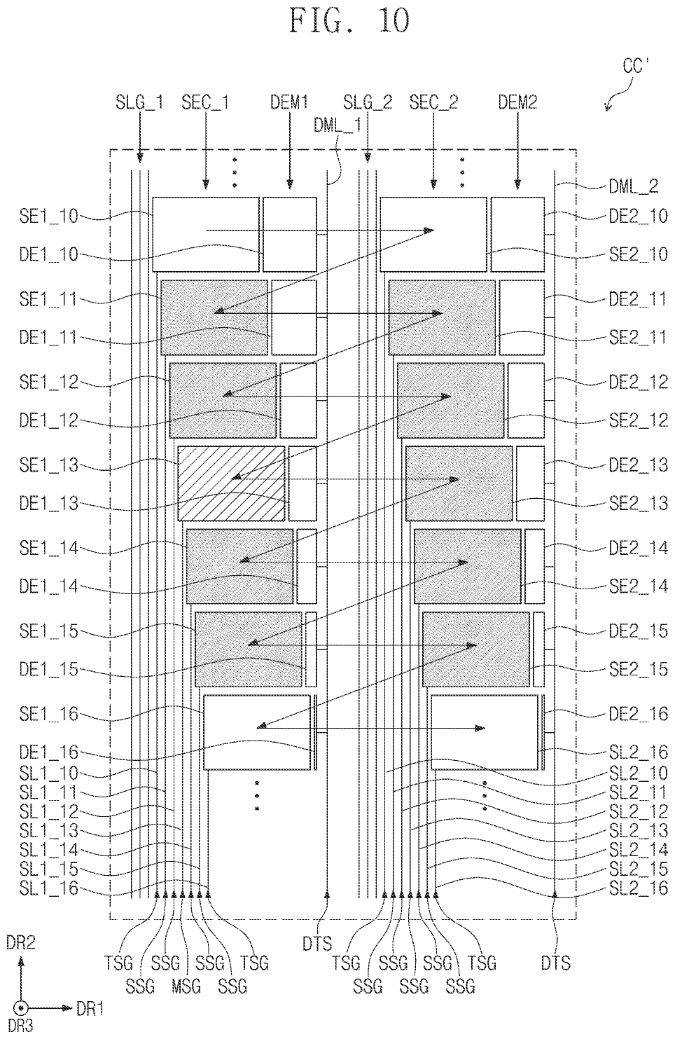

Each of the auxiliary electrodes DE1_1 to DEm_n−1 may be disposed separately from each other. Although the auxiliary electrodes DE1_1 to DEm_n−1 included in each of the auxiliary unit DEM1 to DEMm are separated, the auxiliary electrodes DE1_1 to DEm_n−1 may be electrically connected through the auxiliary lines DML_1 to DML_m included in each of the auxiliary unit DEM1 to DEMm. The auxiliary lines DML_1 to DML_m may apply an auxiliary transmission signal DTS (see FIG. 10) to the auxiliary electrodes DE1_1 to DEm_n−1. For example, the first auxiliary line DML_1 may apply the auxiliary transmission signal DTS having an inverted phase from a peripheral sensing signal SSG (see FIG. 10) to the auxiliary electrodes DE1_1 to DEm_n−1 included in the first auxiliary unit DEM1. Accordingly, destructive interference may occur between the peripheral sensing signal SSG and the auxiliary transmission signal DTS, and the electromagnetic interference (EMI) may be improved by the generated destructive interference. The details will be described later.

Referring to FIG. 7A and FIG. 7B, the area where the sensing electrodes SE1_1 to SEm_n are disposed may be defined as a first area A1, the area where the auxiliary electrodes DE1_1 to DEm_n−1 are disposed is defined as a second area A2, and the area where the sensing lines SL1_1 to SLm_n are disposed may be defined as a third area A3. The first area A1, the second area A2 and the third area A3 may be included in the sensing area SA.

According to an embodiment of the present disclosure, the first areas A1 may have the same size. That is, the sizes of the sensing electrodes SE1_1 to SEm_n may be the same. Because the first areas A1 correspond to the sensing electrodes SE1_1 to SEm_n, the first areas A1 may be arranged in the first direction DR1 and the second direction DR2. Distances between the first areas A1 arranged in the first direction DR1 may be the same as each other. As the sizes of the first areas A1 where the sensing electrodes SE1_1 to SEm_n are disposed are the same and the distance between the first areas A1 arranged in the first direction DR1 is constant, the sensing of the input sensor ISP of the present disclosure may be elaborated.

According to an embodiment of the present disclosure, the size of the second area A2 may vary in the second direction DR2. In detail, the area of the second area A2 may gradually decrease with decreasing distance to the sensor controller TIC. As the first areas A1 become closer to the sensor controller TIC, corresponding to the shift of the second area A2 in the first direction DR1, the area of the second area A2 may gradually decrease with proximity to the sensor controller TIC. The sizes of the second areas A2 disposed in the first direction DR1 may be constant.

According to an embodiment of the present disclosure, at least one of the second area A2 and the third area A3 may be disposed between the first areas A1 as areas arranged in the first direction DR1. That is, as areas arranged in the first direction DR1, at least one of the auxiliary units DEM1 to DEMm or the sensing lines SL1_1 to SLm_n may be disposed between the first areas A1. The third area A3 may be disposed adjacent to the first areas A1 and the second area A2 may also be disposed adjacent to the first areas A1. Accordingly, the first areas A1 may be disposed between the second area A2 and the third area A3.

Referring to FIG. 7A, the sensor controller TIC may be connected to the sensing lines SL1_1 to SLm_n and the auxiliary lines DML_1 to DML_m, and a main sensing signal MSG (see FIG. 10), the peripheral sensing signal SSG (see FIG. 10), and a reference signal TSG (see FIG. 10) may be applied to the sensing lines SL1_1 to SLm_n, and an auxiliary transmission signal DTS may be applied to auxiliary lines DML_1 to DML_m. The sensor controller TIC may calculate the coordinate information of the input based on the signal received from the input sensor ISP and provide the coordinate signal having the coordinate information to the main controller. The main controller may execute an operation corresponding to the input based on the coordinate signal.

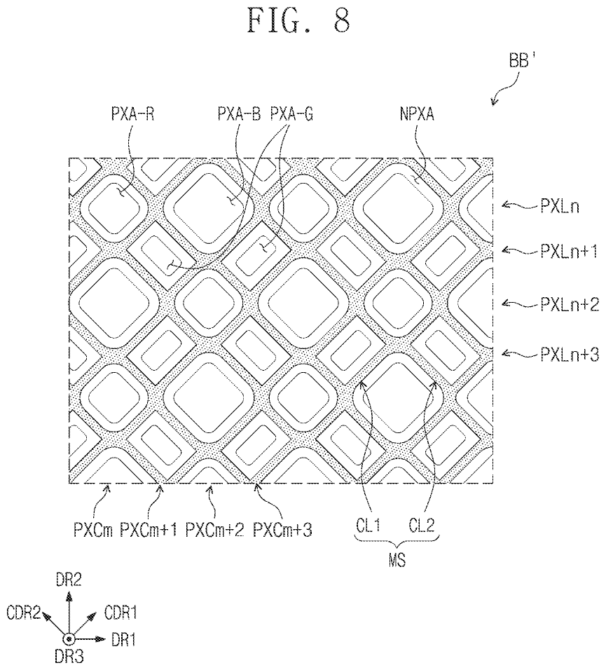

FIG. 8 is an enlarged view illustrating a portion corresponding to area BB′ of FIG. 7A. FIG. 8 may be a plan view illustrating a portion of the input sensor ISP (see FIG. 6) disposed on the display panel DP (see FIG. 6). Redundant descriptions will be omitted below.

Referring to FIGS. 7A and 8, the sensing electrodes SE1_1 to SEm_n may include a plurality of sensing patterns MS forming a mesh shape or a lattice shape. The sensing patterns MS may include first lines CL1 extending in the first diagonal direction CDR1 and second lines CL2 extending in the second diagonal direction CDR2. The first lines CL1 and the second lines CL2 correspond to the first conductive layer CL of the input sensor (see FIG. 6).

None of the first lines CL1 has a perfect straight line shape in the first diagonal direction CDR1 and may include a plurality of straight sections and a plurality of curved sections. In addition, the second lines CL2 may also include a plurality of straight areas and a plurality of curved areas. The first lines CL1 and the second lines CL2 may not overlap the light emitting areas PXA-R, PXA-G, and PXA-B. That is, the first lines CL1 and the second lines CL2 may overlap the non-emission area NPXA. The first lines CL1 and the second lines CL2 may be disposed along the shape on the plane of the light emitting areas PXA-R, PXA-G, and PXA-B outside the light emitting areas PXA-R, PXA-G, and PXA-B.

Meanwhile, the shape of the plurality of sensing patterns MS shown in FIG. 8 is exemplary, and the embodiment is not limited thereto.

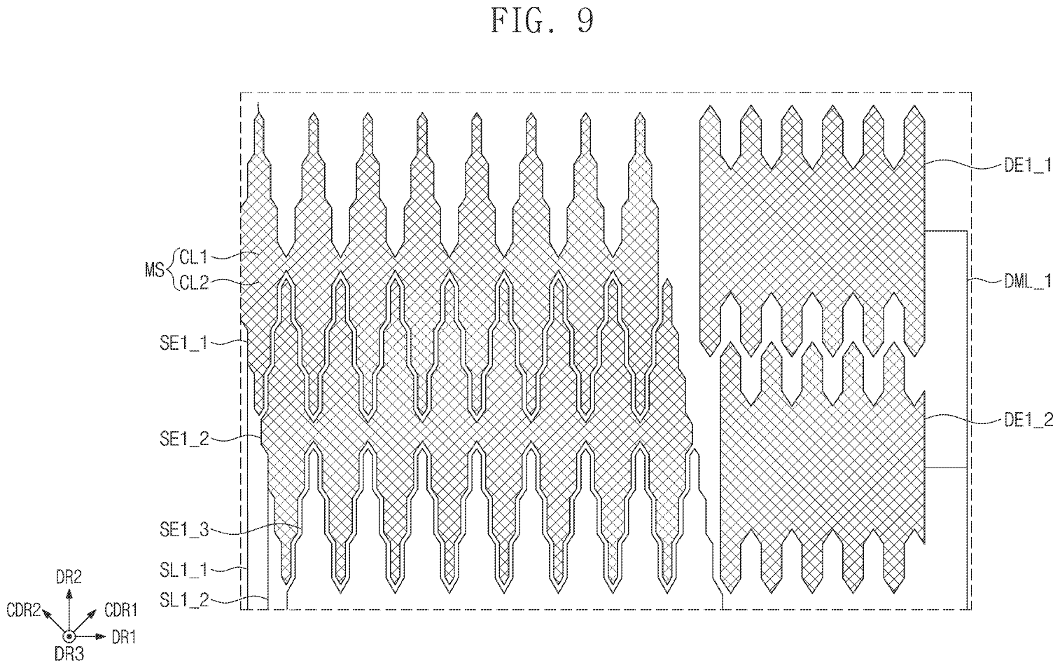

FIG. 9 is an enlarged view illustrating a portion corresponding to a portion of the sensing electrode and a portion of the auxiliary unit of FIG. 7A. In addition, FIG. 9 is a view illustrating portions of the first sensing electrode column SEC_1, the first auxiliary unit DEM1, and the first line group SLG_1 of FIG. 7A.

Referring to FIG. 9, the first sensing electrode SE1_1 and the second sensing electrode SE1_2 included in the first sensing electrode column SEC_1 (see FIG. 7A), and the first auxiliary electrode DE1_1 and the second auxiliary electrode DE1_2 included in the first auxiliary unit DEM1 (see FIG. 7A) may have a mesh shape. In detail, each of the first sensing electrode SE1_1, the second sensing electrode SE1_2, the first auxiliary electrode DE1_1, and the second auxiliary electrode DE1_2, which is the sensing pattern MS, may include the first lines CL1 extending in the first diagonal direction CDR1 and the second lines CL2 extending in the second diagonal direction CDR2.

The first sensing electrode SE1_1 and the second sensing electrode SE1_2 may have the same shape as each other. In detail, the first sensing electrode SE1_1 and the second sensing electrode SE1_2 may have eight peaks on top and bottom, and may have a shape interdigitated with each other. The second sensing electrode SE1_2 may be disposed to allow the peak formed on an upper portion of the second sensing electrode SE1_2 to be interdigitated with the peak formed on a lower portion of the first sensing electrode SE1_1, but the first sensing electrode SE1_1 and the second sensing electrode SE1_2 may be disposed separated from each other based on a boundary area.

Because the second sensing electrode SE1_2 is arranged interdigitated with the first sensing electrode SE1_1, the second sensing electrode SE1_2 may be disposed at a position that is shifted in the first direction DR1 with respect to the first sensing electrode SE1_1. In detail, the second sensing electrode SE1_2 may be disposed at a position shifted in the first direction DR1 by a half distance of the peak formed on the first sensing electrode SE1_1. The same description may be applied to the third sensing electrode SE1_3 disposed below the second sensing electrode SE1_2. Accordingly, as shown in FIG. 7A, the sensing electrodes SE1_1 to SE1_n included in the first sensing electrode column SEC_1 (see FIG. 7A) may be shifted to the first direction DR1 on the second direction DR2.

The shapes of the first sensing electrode SE1_1 and the second sensing electrode SE1_2 are not limited to those shown in FIG. 9. Although the number of peaks is shown as eight in FIG. 9, the number of peaks formed on the first sensing electrode SE1_1 and the second sensing electrode SE1_2 may be eight or more.

The first sensing line SL1_1 and the second sensing line SL1_2 may be connected to the first sensing electrode SE1_1 and the second sensing electrode SE1_2, respectively. The first sensing line SL1_1 may be disposed at one side of the first sensing electrode SE1_1 to be connected to the sensing pattern MS, and non-overlap with the sensing electrodes SE1_2 to SE1_n other than the first sensing electrode SE1_1 in the second direction DR2. Similarly, the second sensing line SL1_2 may be disposed at one side of the second sensing electrode SE1_2 to be connected to the sensing pattern MS, and non-overlap with the sensing electrodes SE1_1, and SE1_3 to SE1_n other than the second sensing electrode SE1_2 in the second direction DR2. As the sensing lines SL1_1 to SLm_n shown in FIG. 7a do not overlap with the sensing electrodes SE1_1 to SEm_n other than the sensing electrodes SE1_1 to SEm_n connected to the sensing lines SL1_1 to SLm_n, respectively, during the sensing operation, the sensing capability of the input sensor ISP (see FIG. 7a) may not be deteriorated.

The first auxiliary electrode DE1_1 and the second auxiliary electrode DE1_2 may be spaced apart from the first sensing electrode SE1_1 and the second sensing electrode SE1_2 in the first direction DR1. The first auxiliary electrode DE1_1 may correspond to the first sensing electrode SE1_1, and the second auxiliary electrode DE1_2 may correspond to the second sensing electrode SE1_2. Each of the first auxiliary electrode DE1_1 and the second auxiliary electrode DE1_2 may be spaced apart from each of the first sensing electrode SE1_1 and the second sensing electrode SE1_2. Accordingly, each of the first auxiliary electrode DE1_1 and the second auxiliary electrode DE1_2 may not be electrically connected to each of the first sensing electrode SE1_1 and the second sensing electrode SE1_2.

The first auxiliary electrode DE1_1 and the second auxiliary electrode DE1_2 may be spaced apart from each other in the second direction DR2. In detail, the first auxiliary electrode DE1_1 and the second auxiliary electrode DE1_2 may have a plurality of peak shapes, and the first auxiliary electrode DE1_1 and the second auxiliary electrode DE1_2 are partially interdigitated with each other. The sizes of the first auxiliary electrode DE1_1 and the second auxiliary electrode DE1_2 may be different from each other. For example, the size of the second auxiliary electrode DE1_2 may be smaller than that of the first auxiliary electrode DE1_1. As shown in FIG. 7A, the same description may be applied to the auxiliary electrodes DE1_1 to DEm_n−1. Accordingly, the sizes of the auxiliary electrodes DE1_1 to DEm_n−1 may gradually decrease toward the sensor controller TIC.

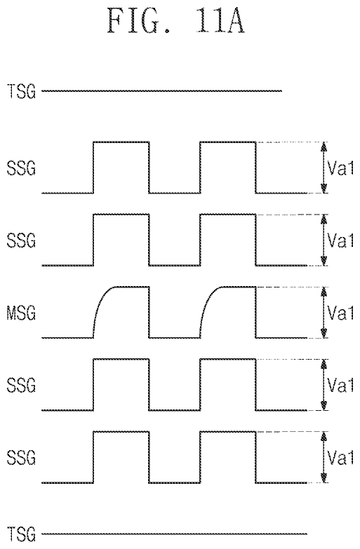

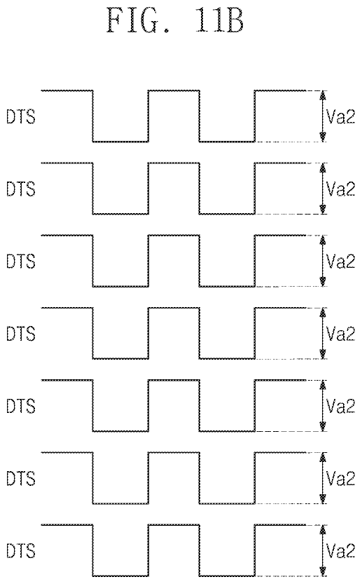

FIG. 10 is an enlarged view illustrating a portion corresponding to an area CC′ of FIG. 7A. FIG. 11A is a diagram illustrating transmission signals applied to the sensing electrodes shown in FIG. 10. FIG. 11B is a diagram illustrating transmission signals applied to the auxiliary electrodes shown in FIG. 10. Hereinafter, a sensing operation will be described in detail with reference to FIGS. 10 to 11B.

In FIG. 10, a portion of the first sensing electrode column SEC_1, the second sensing electrode column SEC_2, the first auxiliary unit DEM1, the second auxiliary unit DEM2, the first line group SLG_1, and the second line group SLG_2 are shown. FIG. 10 illustrates seven sensing electrodes included in the first sensing electrode column SEC_1 and seven sensing electrodes included in the second sensing electrode column SEC_2. For example, the seven sensing electrodes included in the first sensing electrode column SEC_1 may correspond to the tenth to sixteenth sensing electrodes SE1_10 to SE1_16, and the seven sensing electrodes included in the second sensing electrode column SEC_2 may correspond to the 20-th to 26-th sensing electrodes SE2_10 to SE2_16. Correspondingly, the seven sensing lines included in the first line group SLG_1 shown in FIG. 10 may correspond to the tenth to sixteenth sensing lines SL1_10 to SL1_16, and the seven sensing lines included in the second line group SLG_2 may correspond to the 20-th to 26-th sensing lines SL2_10 to SL2_16. In addition, one auxiliary line and seven auxiliary electrodes included in the first auxiliary unit DEM1 shown in FIG. 10 may correspond to the first auxiliary line DML_1 and the tenth to sixteenth auxiliary electrodes DE1_10 to DE1_16, and one auxiliary line and seven auxiliary electrodes included in the second auxiliary unit DEM2 may correspond to the second auxiliary line DML_2 and the 20-th to the 26-th auxiliary electrodes DE2_10 to DE1_26.

The input sensor ISP (see FIG. 7A) according to an embodiment of the present disclosure may perform a sensing operation with respect to the sensing electrodes SE1_1 to SEm_n (see FIG. 7A). As shown in FIG. 10, the 10-th to 16-th sensing electrodes SE1_10 to SE1_16 and the 20-th to 26-th sensing electrodes SE2_10 to SE2_16 may be driven in the order of ‘Z’. In detail, the 26-th sensing electrode SE2_16 may be driven in the order of the 20-th sensing electrode SE2_10 after the 10-th sensing electrode SE1_10, and the 11-th sensing electrode SE1_11 after the 20-th sensing electrode SE2_10. That is, the 10-th to 16-th sensing electrodes SE1_10 to SE1_16 and the 20-th to 26-th sensing electrodes SE2_10 to SE2_16 may be driven in the order indicated by the arrows in FIG. 10 (resembling a series of ‘Z’s) from the 10-th sensing electrode SE1_10 to the 26-th sensing electrode SE2_16. FIG. 10 exemplarily illustrates that the 13-th sensing electrode SE1_13 is driven.

The 10-th to 16-th sensing lines SL1_10 to SL1_16 and the 20-th to 26-th sensing lines SL2_10 to SL2_16 may be connected to the 10-th to 16-th sensing electrodes SE1_10 to SE1_16 and the 20-th to 26-th sensing electrodes SE2_10 to SE2_16, respectively. The 10-th to 16-th sensing electrodes SE1_10 to SE1_16 and the 20-th to 26-th sensing electrodes SE2_10 to SE2_16 may receive transmission signals from the 10-th to 16-th sensing lines SL1_10 to SL1_16 and the 20-th to 26-th sensing lines SL2_10 to SL2_16, respectively.

The 13-th sensing electrode SE1_13 performing a sensing operation will be referred to as the main sensing electrode SE1_13. In addition, the 11-th, 12-th, 14-th, and 15-th sensing electrodes SE1_11, SE1_12, SE1_14, and SE1_15 and the 20-th to 26-th sensing electrodes SE2_10 to SE2_16 disposed around the main sensing electrode SE1_13 will be referred to as the peripheral sensing electrodes SE1_11, SE1_12, SE1_14, SE1_15, and SE2_10 to SE2_16. The 10-th sensing electrode SE1_10, the 16-th sensing electrode SE1_16, the 20-th sensing electrode SE2_10, and the 26-th sensing electrode SE2_16 adjacent to the peripheral sensing electrodes will be referred to as reference sensing electrodes SE1_10, SE1_16, SE2_10, and SE2_16.

The 10-th to 16-th sensing electrodes SE1_10 to SE1_16 and the 20-th to 26-th sensing electrodes SE2_10 to SE2_16 may receive the main sensing signal MSG, the peripheral sensing signal SSG and the reference signal TSG from the 10-th to 16-th sensing lines SL1_10 to SL1_16 and the 20-th to 26-th sensing lines SL2_10 to SL2_16. The main sensing signal MSG may be applied to the main sensing electrode SE1_13 through the 13-th sensing line SL1_13. The peripheral sensing signal SSG may be applied from the 11-th, 12-th, 14-th, and 15-th sensing lines SL1_11, SL1_12, SL1_14, and SL1_15 and the 20-th to 26-th sensing lines SL1_10 to SL1_16 to the peripheral sensing electrodes SE1_11, SE1_12, SE1_14, SE1_15, and SE2_10 to SE2_16. The reference signal TSG may be applied from the 10-th, 16-th, 20-th, and 26-th sensing lines SL1_10, SL1_16, SL2_10, and SL2_16 to the reference sensing electrodes SE1_10, SE1_16, SE2_10, and SE2_16.

FIG. 11A is a view illustrating the main sensing signal MSG applied to the main sensing electrode SE1_13, the peripheral sensing signal SSG applied to the peripheral sensing electrodes SE1_11, SE1_12, SE1_14, SE1_15, SE2_10 to SE2_16, and the reference signal TSG applied to the reference sensing electrodes SE1_10, SE1_16, SE2_10, and SE2_16. The main sensing signal MSG, the peripheral sensing signal SSG, and the reference signal TSG may have different waveforms.

Referring to FIG. 11A together, the main sensing signal MTS applied to the main sensing electrode SE1_13 may be a square wave signal having a first amplitude Va1. In detail, each waveform may form a waveform in which the first amplitude Va1 is gradually formed at an upper edge and the amplitude is gradually lowered at a lower edge, without immediately forming the first amplitude Va1. The main sensing signal MTS may be provided to the main sensing electrode SE1_13 during the driving period of the main sensing electrode SE1_13.

The reference signal GTS may be a DC signal having a ground voltage. However, the embodiments of the present disclosure are not limited thereto, and the reference signal may be a signal having a voltage other than the ground voltage. Although not shown, the reference signal TSG may be applied to the reference sensing electrodes SE1_10, SE1_16, SE2_10, and SE2_16 by connecting a line connected to the reference signal TSG to a separate ground terminal. The reference signal TSG may be applied to the reference sensing electrodes SE1_10, SE1_16, SE2_10, and SE2_16 during the driving period of the main sensing electrode SE1_13. During the driving period of the main sensing electrode SE1_13, external static electricity may be applied to the periphery of the main sensing electrode SE1_13. In this case, external static electricity may be discharged to the ground terminal. The reference signal TSG is not always applied to the reference sensing electrodes SE1_10, SE1_16, SE2_10, and SE2_16 and may not be applied to the reference sensing electrodes SE1_10, SE1_16, SE2_10, and SE2_16.

The peripheral sensing signal SSG may include a waveform having a predetermined amplitude. In detail, the peripheral sensing signal SSG may be a square wave signal having the same first amplitude Va1 as that of the main sensing signal MSG. The peripheral sensing signal SSG may be provided to the peripheral sensing electrodes SE1_11, SE1_12, SE1_14, SE1_15, and SE2_10 to SE2_16 during the driving period of the main sensing electrode SE1_13. The peripheral sensing signal SSG may not be always applied to the peripheral sensing electrodes SE1_11, SE1_12, SE1_14, SE1_15, and SE2_10 to SE2_16 and may not be applied to the peripheral sensing electrodes SE1_11, SE1_12, SE1_14, SE1_15, and SE2_10 to SE2_16.

A coupling phenomenon may occur between the reference signal TSG and the main sensing signal MSG due to a potential difference between the reference signal TSG and the main sensing signal MSG. That is, noise may be generated due to mutual signal interference. To reduce noise, the peripheral sensing signal SSG having a predetermined level may be applied to the peripheral sensing electrodes SE1_11, SE1_12, SE1_14, SE1_15, and SE2_10 to SE2_16. In detail, a coupling phenomenon between the reference signal TSG and the main sensing signal MSG may be reduced by applying the peripheral sensing signal SSG having the same first amplitude Va1 as the main sensing signal MSG.

When sensing occurs in the main sensing electrode SE1_13, the sensor controller TIC (see FIG. 7A) may detect the degree of change from the main sensing signal MSG to determine the sensing. Specifically, the sensor controller TIC may apply the main sensing signal MSG to the main sensing electrode SE1_13, and detect the change in the main sensing signal MSG formed through the change in capacitance through sensing of the main sensing signal MSG by sensing in the main sensing electrode SE1_13, thereby determining whether sensing is performed. The sensor controller TIC may perform sensing by applying only the main sensing signal MSG to the main sensing electrode SE1_13, but in the present disclosure, the sensor controller TIC may apply the peripheral sensing signal SSG to the peripheral sensing electrodes SE1_11, SE1_12, SE1_14, SE1_15, and SE2_10 to SE2_16, and additionally apply the reference signal TSG to the reference sensing electrodes SE1_10, SE1_16, SE2_10, and SE2_16, thereby providing the input sensor ISP (see FIG. 7A) having improved sensing characteristics.

Referring to FIG. 10 again, the first auxiliary line DML_1 may be connected to the 10-th to 16-th auxiliary electrodes DE1_10 to DE1_16, and the second auxiliary line DML_2 may be connected to the 20-th to 26-th auxiliary electrodes DE2_10 to DE1_26. The 10-th to 16-th auxiliary electrodes DE1_10 to DE1_16 and the 20-th to 26-th auxiliary electrodes DE2_10 to DE1_26 may receive transmission signals from the first auxiliary line DML_1 and the second auxiliary line DML_2.

While the sensing operation of the main sensing electrode SE1_13 is performed, the 10-th to 16-th auxiliary electrodes DE1_10 to DE1_16 and the 20-th to 26-th auxiliary electrodes DE2_10 to DE1_26 may receive the auxiliary transmission signal DTS. Specifically, the 10-th to 16-th auxiliary electrodes DE1_10 to DE1_16 may receive the auxiliary transmission signal DTS from the first auxiliary line DML_1, and the 20-th to 26-th auxiliary electrodes DE2_10 to DE1_26 may receive the auxiliary transmission signal DTS from the second auxiliary line DML_2.

FIG. 11B is a view illustrating the auxiliary transmission signal DTS applied to the 10-th to 16-th auxiliary electrodes DE1_10 to DE1_16 or the 20-th to 26-th auxiliary electrodes DE2_10 to DE1_26. The auxiliary transmission signal DTS may have a different waveform from those of the main sensing signal MSG and the reference signal TSG shown in FIG. 11A. The auxiliary transmission signal DTS may have the same waveform as the peripheral sensing signal SSG, but may have a phase inverted from that of the peripheral sensing signal SSG. The auxiliary transmission signal DTS may be a square wave signal having a second amplitude Va2. According to an embodiment of the present disclosure, the first amplitude Va1 and the second amplitude Va2 may be the same. However, the embodiment is not limited thereto, and the first amplitude Va1 and the second amplitude Va2 may be different from each other, and the second amplitude Va2 may be greater than the first amplitude Va1.

When sensing is performed through the main sensing electrode SE1_13, electromagnetic waves may be emitted as unnecessary electromagnetic signals due to the main sensing signal MSG and the peripheral sensing signal SSG having a high frequency. The electromagnetic signals act as noise (electromagnetic interference: EMI) to other devices, and may interfere with the operation of other devices. For example, electromagnetic signals generated from the main sensing signal MSG and the peripheral sensing signal SSG may affect the operation of the display panel DP (see FIG. 6). During a sensing operation, the auxiliary transmission signal DTS may have an opposite phase to the periphery sensing signal SSG. Because the auxiliary transmission signal DTS has an opposite phase to the peripheral sensing signal SSG, the electromagnetic signal may be offset by the auxiliary transmission signal DTS. That is, by applying the auxiliary transmission signal DTS having the opposite phase to the peripheral sensing signal SSG to the auxiliary electrode corresponding to the driven sensing electrode, electromagnetic signals generated from the input sensor ISP (see FIG. 7A) due to the auxiliary transmission signal DTS may be offset.

Specifically, the electromagnetic signal may be adjusted according to the size of the area where an electrode is disposed. In the present disclosure, because the sizes of the auxiliary electrodes DE1_1 to DEm_n−1 (see FIG. 7A) increase as they are disposed in the second direction DR2, the electromagnetic signal generated at the upper end of the input sensor ISP may be more efficiently offset. Accordingly, it is possible to improve operation reliability of the input sensor ISP according to an embodiment of the present disclosure.

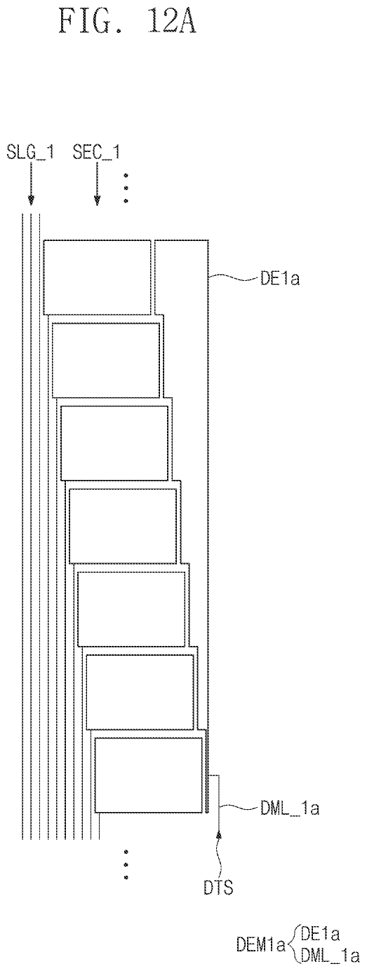

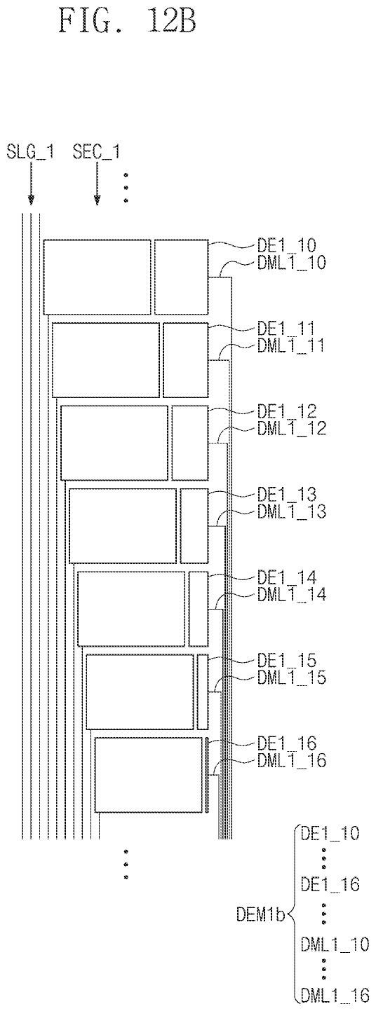

FIG. 12A is a plan view illustrating a portion of an input sensor according to an embodiment of the present disclosure. Hereinafter, matters overlapping with those described above will be omitted.

Referring to FIG. 12A, a first auxiliary unit DEM1a may include an auxiliary electrode DE1a and an auxiliary line DML_1a connected to the auxiliary electrode DE1a. When the auxiliary electrode DE1a is compared with the auxiliary electrodes DE1_10 to DE1_16 included in the first auxiliary unit DEM1 shown in FIG. 10, the auxiliary electrode DE1a may be formed by integrally connecting the auxiliary electrodes DE1_10 to DE1_16 of FIG. 10.

The width of the auxiliary electrode DE1a in the first direction DR1 may gradually decrease in a direction opposite to the second direction DR2 corresponding to the shape of the first sensing electrode column SEC_1. The auxiliary electrode DE1a may receive the auxiliary transmission signal DTS from the second auxiliary line DML_2. The auxiliary electrode DE1a of FIG. 10 is formed by integrally connecting a plurality of auxiliary electrodes, but is not limited thereto, and may be formed by connecting only some of the plurality of auxiliary electrodes to each other. Although the first auxiliary unit DEM1a is exemplarily described in FIG. 12A, the same description may be applied to a second auxiliary unit, which is not shown.

FIG. 12B is a plan view illustrating a portion of an input sensor according to an embodiment of the present disclosure.

Referring to FIG. 12B, a first auxiliary unit DEM1b may include auxiliary electrodes DE1_10 to DE1_16 and a plurality of auxiliary lines DML1_10 to DML1_16. The auxiliary lines DML1_10 to DML1_16 may be electrically connected to the auxiliary electrodes DE1_10 to DE1_16 to apply the auxiliary transmission signal DTS (see FIG. 12A) to the auxiliary electrodes DE1_10 to DE1_16.

The auxiliary lines DML1_10 to DML1_16 according to an embodiment of the present disclosure may individually apply the auxiliary transmission signal DTS (see FIG. 10) having the phase opposite to that of the peripheral sensing signal SSG (see FIG. 10) to the auxiliary electrode corresponding to the sensing electrode on which the sensing operation is performed, so that it is possible to effectively offset the electromagnetic signal generated by the peripheral sensing signal SSG. Accordingly, it is possible to provide a reliable input sensor ISP (see FIG. 7A). Although the first auxiliary unit DEM1b is exemplarily described in FIG. 12B, the same description may be applied to a second auxiliary unit, which is not shown.

While the present disclosure has been described with reference to embodiments thereof, it will be apparent to those of ordinary skill in the art that various changes and modifications may be made thereto without departing from the spirit and scope of the present disclosure as set forth in the following claims.

Therefore, the technical scope of the present disclosure is not limited to the contents described in the detailed description of the specification, but should be defined by the claims.

What is claimed is:

1. A display device comprising:
a display panel configured to display an image;
an input sensor disposed on the display panel and including a sensing area and a sensing peripheral area; and
a sensor controller configured to drive the sensing area,
wherein the input sensor includes:
a plurality of sensing electrodes arranged in a first direction and a second direction perpendicular to the first direction; and
an auxiliary unit disposed at one side of at least one of the sensing electrodes,
wherein a main sensing electrode among the sensing electrodes is configured to receive a main sensing signal from the sensor controller,
a peripheral sensing electrode adjacent to the main sensing electrode among the sensing electrodes is configured to receive a peripheral sensing signal from the sensor controller, and
the auxiliary unit is configured to receive an auxiliary transmission signal from the sensor controller, the auxiliary transmission signal having an inverted phase from the peripheral sensing signal.

2. The display device of claim 1, wherein the auxiliary unit includes:
a plurality of auxiliary electrodes arranged in the second direction; and
an auxiliary line electrically connected to the auxiliary electrode.

3. The display device of claim 2, wherein the auxiliary electrodes are disposed at one side of the sensing electrodes and correspond to the sensing electrodes.

4. The display device of claim 3, wherein each of the auxiliary electrodes is connected to the auxiliary line, and
the auxiliary electrodes are configured to receive the same auxiliary transmission signal from the auxiliary line.

5. The display device of claim 3, wherein the auxiliary line includes a plurality of auxiliary lines, and
each of the auxiliary electrodes is configured to receive the auxiliary transmission signal from the plurality of auxiliary lines connected to each of the auxiliary electrodes.

6. The display device of claim 3, wherein the auxiliary electrodes are integrally connected.

7. The display device of claim 3, wherein the sensing electrodes and the auxiliary electrodes corresponding to the sensing electrodes are electrically insulated from one another.

8. The display device of claim 1, wherein an amplitude of the peripheral sensing signal is equal to an amplitude of the auxiliary transmission signal.

9. The display device of claim 1, wherein the input sensor further includes a plurality of sensing lines connected to each of the sensor controller and the sensing electrodes, and
the sensing lines connected to the sensing electrodes are disposed on another side opposite to one side of the sensing electrodes in the first direction.

10. The display device of claim 9, wherein the sensing electrodes, the sensing lines and the auxiliary unit are disposed on a same layer.

11. The display device of claim 9, wherein the sensing electrodes are disposed between the sensing lines and the auxiliary unit.

12. The display device of claim 9, wherein an area where the sensing electrodes are disposed is defined as a first area,
an area where auxiliary electrodes are disposed is defined as a second area,
an area where the sensing lines are disposed is defined as a third area, and
each of the first area, the second area and the third area is included in the sensing area.

13. The display device of claim 12, wherein the first area includes a plurality of first areas, and the first areas have a same size.

14. The display device of claim 13, wherein distances between the first areas arranged in the first direction are equal to each other.

15. The display device of claim 14, wherein at least one of the auxiliary unit or the sensing lines is disposed between the first areas arranged in the first direction.

16. The display device of claim 12, wherein a size of the second area gradually decreases with decreasing distance to the sensor controller.

17. The display device of claim 12, wherein a size of the third area gradually increases with decreasing distance to the sensor controller.

18. The display device of claim 12, wherein the second area includes a plurality of second areas, and the second areas disposed in the first direction have a constant size.

19. The display device of claim 1, wherein the sensing electrodes further include a reference sensing electrode adjacent to the peripheral sensing electrode.

20. The display device of claim 19, wherein the reference sensing electrode is configured to receive a reference signal from the sensor controller.

21. A display device comprising:
a display panel configured to display an image;
an input sensor disposed on the display panel and including a sensing area and a sensing peripheral area; and
a sensor controller configured to drive the sensing area,
wherein the input sensor includes:
a plurality of sensing electrodes arranged in a first direction and a second direction perpendicular to the first direction; and
an auxiliary unit disposed at one side of the sensing electrodes and including a plurality of auxiliary electrodes and an auxiliary line electrically connecting the auxiliary electrodes to the sensor controller,
wherein each of the sensing electrodes is configured to receive a first transmission signal from the sensor controller through the plurality of sensing lines, and
the plurality of auxiliary electrodes are configured to receive a second transmission signal having an inverted phase from the first transmission signal from the sensor controller through the auxiliary line.
